(19) United States
(12) Patent Application Publication
(10) Pub. No.: US 2025/0241141 A1
(43) Pub. Date: Jul. 24, 2025

(54) Display Device

(71) Applicant: LG Display Co., Ltd., Seoul (KR)

(72) Inventors: JiHyun Roh, Paju-si (KR); Mingeun Song, Paju-si (KR); KwanSoo Kim, Paju-si (KR); JongWoo Park, Paju-si (KR); SeokHyun Kim, Paju-si (KR)

(21) Appl. No.: 19/000,966

(22) Filed: Dec. 24, 2024

(30) Foreign Application Priority Data
Jan. 22, 2024 (KR) 10-2024-0009604

(51) Int. Cl. H10K 59/124

(52) U.S. Cl. CPC H10K 59/124

(57) ABSTRACT

A display device may include a substrate including a display area capable of displaying an image, and an insulating layer on the substrate. The display area may include a first display area with a plurality of emission areas and a transmission area, and a second display area located outside the first display area and with a plurality of emission areas. Each of the plurality of emission areas may include a pixel electrode on the insulating layer, a first organic layer located on the pixel electrode and including an emission layer, and a common electrode on the first organic layer. The transmission area may include a second organic layer on the insulating layer, a patterning layer on the second organic layer, and a residual film located on the patterning layer.

### CROSS REFERENCE TO RELATED APPLICATION

This application claims priority from Republic of Korea Patent Application No. 10-2024-0009604, filed on Jan. 22, 2024, which is hereby incorporated by reference in its entirety.

### TECHNICAL FIELD

Embodiments of the present disclosure relate to a display device.

### BACKGROUND

As technology advances, a display device may provide shooting functions and various sensing functions in addition to image display functions. Accordingly, a display device is required to be equipped with electronic devices such as a camera and a detection sensor (which may also be referred to as a light receiving device or sensor).

Since an electronic device may receive light from the front of a display device, so the electronic device is required to be installed in a location capable of receiving the light. Therefore, a camera (i.e., a camera lens) and a detection sensor have to be installed to be exposed to the front of a display device. As a result, a bezel of the display device may become larger or a camera or detection sensor may be installed in a notch or physical hole formed in a display area of the display panel.

Accordingly, as a display device is equipped with electronic devices such as cameras and detection sensors which receive light from the front and perform a specific function, the bezel on the front of the display device may become larger or restrictions may occur in the front design of the display device. In addition, in the case that a display device includes an electronic device, there may be occurred unexpected image quality deterioration depending on a structure for including the electronic device.

### SUMMARY

Embodiments of the present disclosure may provide a display device having a light transmission structure which allows an electronic device located below a display panel to normally receive light without exposing the electronic device receiving light to the front.

Embodiments of the present disclosure may provide a display device which does not deteriorate image quality even when irradiated with ultraviolet rays.

Embodiments of the present disclosure may provide a display device capable of prevent gas release and pixel shrinkage even when irradiated with ultraviolet rays.

Embodiments of the present disclosure may provide a display device having an ultraviolet barrier structure in a transmission area.

A display device according to embodiments of the present disclosure may include a substrate including a display area capable of displaying an image, and an insulating layer on the substrate.

The display area may include a first display area with a plurality of emission areas and a transmission area, and a second display area located outside the first display area and with a plurality of emission areas.

Each of the plurality of emission areas may include a pixel electrode on the insulating layer, a first organic layer located on the pixel electrode and including an emission layer, and a common electrode on the first organic layer.

The transmission area may include a second organic layer on the insulating layer, a patterning layer on the second organic layer, and a residual film located on the patterning layer.

According to the embodiments of the present disclosure, there may provide a display device having a light transmission structure which allows an electronic device located below a display panel to normally receive light without exposing the electronic device receiving light to the front.

According to the embodiments of the present disclosure, there may provide a display device which does not deteriorate image quality even when irradiated with ultraviolet rays.

According to the embodiments of the present disclosure, there may provide a display device capable of prevent gas release and pixel shrinkage even when irradiated with ultraviolet rays.

According to the embodiments of the present disclosure, there may provide a display device having an ultraviolet barrier structure in a transmission area.

According to the embodiments of the present disclosure, there may provide a display device with reduced manufacturing costs through process optimization by utilizing the required processes to form a residual film acting as an ultraviolet ray barrier in the transmission area.

The effects of the present disclosure are not limited to the effects described above, and other effects not described will be clearly understood by those skilled in the art from the description below.

### BRIEF DESCRIPTION OF THE DRAWINGS

FIGS. 1A, 1B and 1C illustrate display devices according to embodiments of the present disclosure.

FIG. 2 illustrates a system configuration diagram of a display device according to embodiments of the present disclosure.

FIG. 3 illustrates a display panel according to embodiments of the present disclosure.

FIG. 4 illustrates a first display area of a first type and a second display area outside a first display area in a display panel according to embodiments of the present disclosure.

FIG. 5 is a plan view of a first display area of a first type in a display panel according to embodiments of the present disclosure.

FIG. 6 is a cross-sectional view of a first display area of a first type in a display panel according to embodiments of the present disclosure.

FIG. 7 illustrates a first display area of a second type, and a second display area and a third display area outside the first display area in a display panel according to embodiments of the present disclosure.

FIGS. 8 and 9 illustrate light emitting devices disposed in each of a first display area of a second type, a second display area and a third display area, and pixel circuits for driving the light emitting device in a display panel according to embodiments of the present disclosure.

FIGS. 10 and 11 are cross-sectional views of a first display area and a third display area in a display panel according to embodiments of the present disclosure.

FIG. 12 illustrates an ultraviolet ray reliability evaluation process of a display panel according to embodiments of the present disclosure.

FIG. 13 illustrates pixel shrinkage phenomenon according to an ultraviolet ray reliability evaluation process of a display panel according to embodiments of the present disclosure.

FIG. 14 is a cross-sectional view of a display panel having an ultraviolet ray reliability improvement structure according to embodiments of the present disclosure.

FIGS. 15 to 17 illustrate a residual film of a display panel according to embodiments of the present disclosure.

FIG. 18 illustrates a deposition sequence for forming a light emitting device forming part of a 1-stack structure in a display panel according to embodiments of the present disclosure.

FIG. 19 illustrates a layer stack of an emission area and a transmission area in a display panel according to embodiments of the present disclosure.

FIG. 20 illustrates a deposition sequence for forming a light emitting device forming part of a 2-stack structure in a display panel according to embodiments of the present disclosure.

FIG. 21 illustrates a layer stack of an emission area and a transmission area in a display panel according to embodiments of the present disclosure.

FIG. 22 illustrates whether of forming a residual film when a material of an electron injection layer includes ytterbium and when a material of an electron injection layer includes ytterbium and lithium fluoride during the manufacturing process of the display panel according to embodiments of the present disclosure.

FIG. 23 illustrates a residual film formed according to a thickness of an electron injection layer when a material of an electron injection layer includes ytterbium and lithium fluoride during the manufacturing process of the display panel according to embodiments of the present disclosure.

FIG. 24 illustrates a transmittance of a first display area including a transmission area of the display panel according to embodiments of the present disclosure.

### DETAILED DESCRIPTION

Hereinafter, embodiments of the disclosure are described in detail with reference to the accompanying drawings. In assigning reference numerals to components of each drawing, the same components may be assigned the same numerals even when they are shown on different drawings. When determined to make the subject matter of the disclosure unclear, the detailed of the known art or functions may be skipped. As used herein, when a component “includes,” “has,” or “is composed of” another component, the component may add other components unless the component “only” includes, has, or is composed of′ the other component. As used herein, the singular forms “a”, “an” and “the” are intended to include the plural forms as well, unless the context clearly indicates otherwise.

Such denotations as “first,” “second,” “A,” “B,” “(a),” and “(b),” may be used in describing the components of the disclosure. These denotations are provided merely to distinguish a component from another, and the essence, order, or number of the components are not limited by the denotations.

In describing the positional relationship between components, when two or more components are described as “connected”, “coupled” or “linked”, the two or more components may be directly “connected”, “coupled” or “linked” “, or another component may intervene. Here, the other component may be included in one or more of the two or more components that are “connected”, “coupled” or “linked” to each other.

When such terms as, e.g., “after”, “next to”, “after”, and “before”, are used to describe the temporal flow relationship related to components, operation methods, and fabricating methods, it may include a non-continuous relationship unless the term “immediately” or “directly” is used.

When a component is designated with a value or its corresponding information (e.g., level), the value or the corresponding information may be interpreted as including a tolerance that may arise due to various factors (e.g., process factors, internal or external impacts, or noise).

Hereinafter, various embodiments of the disclosure are described in detail with reference to the accompanying drawings.

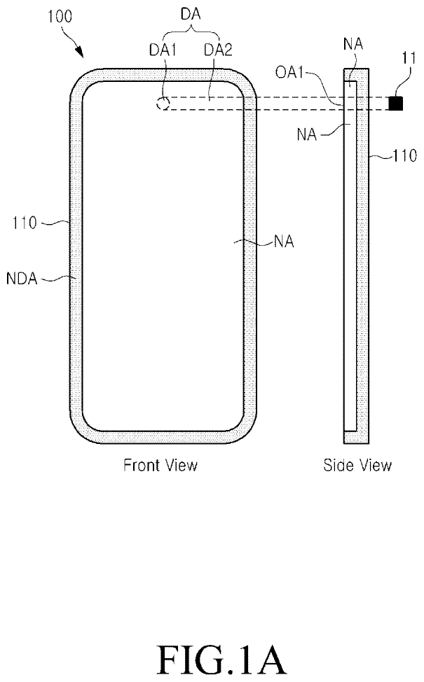

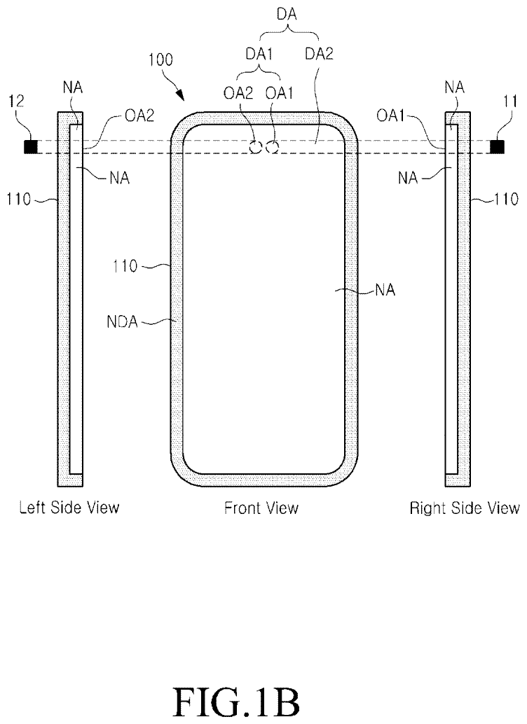

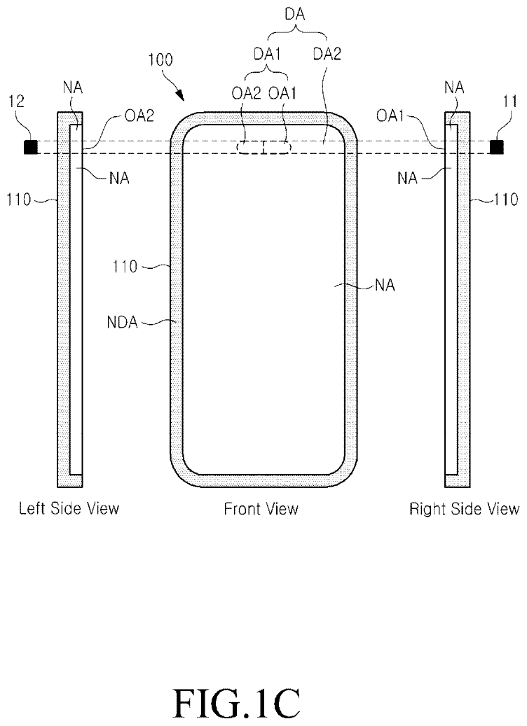

FIGS. 1A, 1B and 1C illustrate a display device 100 according to embodiments of the present disclosure.

Referring to FIGS. 1A, 1B and 1C, a display device 100 according to embodiments of the present disclosure may include a display panel 110 for displaying an image and one or more electronic devices 11 and 12.

The display panel 110 may include a display area DA where an image is displayed and a non-display area NDA where an image is not displayed.

There may be disposed a plurality of subpixels and a plurality of signal lines for driving the plurality of subpixels in the display area DA.

The non-display area NDA may be an area outside the display area DA. Various signal lines may be disposed in the non-display area NDA, and various driving circuits may be connected thereto. The non-display area NDA may be bent so that it is not visible from the front or may be obscured by a case (not shown). The non-display area NDA may be also referred as a bezel or a bezel area.

One or more electronic devices 11 and 12 may be provided and installed separately from the display panel 110, and may be an electronic component located at the lower part of the display panel 110 (i.e., opposite the viewing surface).

The light may enter the front (i.e., viewing side) of the display panel 110, pass through the display panel 110, and may be delivered to one or more electronic devices 11 and 12 located below the display panel 110 (i.e., opposite the viewing surface). For example, light passing through the display panel 110 may include visible light or infrared light.

One or more electronic devices 11 and 12 may be devices which receive light passing through the display panel 110 and perform a predetermined operation using the received light. For example, the one or more electronic devices 11 and 12 may include one or more of a photographing device such as a camera (i.e., image sensor), a detection sensor such as a proximity sensor, and an illuminance sensor. Here, for example, the detection sensor may be an infrared sensor.

The display area DA may include a normal area NA and one or more optical areas OA1 and OA2. One or more optical areas OA1 and OA2 may be areas which overlap with one or more electronic devices 11 and 12.

According to the example of FIG. 1A, the display area DA may include a normal area NA and a first optical area OA1. Here, at least a portion of the first optical area OA1 may overlap with the first electronic device 11.

According to the example of FIG. 1B, the display area DA may include a normal area NA, a first optical area OA1, and a second optical area OA2. In the example of FIG. 1B, the normal area NA may exist between the first optical area OA1 and the second optical area OA2. Here, at least a portion of the first optical area OA1 may overlap with the first electronic device 11, and at least a portion of the second optical area OA2 may overlap with the second electronic device 12.

According to the example of FIG. 1C, the display area DA may include a normal area NA, a first optical area OA1, and a second optical area OA2. In the example of FIG. 1C, there is no normal area NA between the first optical area OA1 and the second optical area OA2. That is, the first optical area OA1 and the second optical area OA2 may be in contact with each other. Here, at least a portion of the first optical area OA1 may overlap with the first electronic device 11, and at least a portion of the second optical area OA2 may overlap with the second electronic device 12.

One or more optical areas OA1 and OA2 are required to include both an image display structure and a light transmission structure. That is, since one or more optical areas OA1 and OA2 are part of the display area DA, emission areas of subpixels for image display are required to be disposed in the one or more optical areas OA1 and OA2. Additionally, a light transmission structure is required to be formed in one or more optical areas OA1 and OA2 to transmit light to one or more electronic devices 11 and 12.

One or more electronic devices 11 and 12 are devices requiring optical reception, and may be located behind (i.e., below or opposite to the viewing surface) the display panel 110 and receive light passing through the display panel 110. One or more electronic devices 11 and 12 may be not exposed to the front (i.e., viewing side) of the display panel 110. Accordingly, when the user looks at the front of the display panel 110, the electronic devices 11 and 12 may be not visible to the user.

For example, a first electronic device 11 may be a camera, and a second electronic device 12 may be a detection sensor such as a proximity sensor or illuminance sensor. For example, the detection sensor may be an infrared sensor for detecting infrared rays. Alternatively, the first electronic device 11 may be a detection sensor, and the second electronic device 12 may be a camera.

Hereinafter, for convenience of explanation, there is exemplified a case in which the first electronic device 11 is a camera and the second electronic device 12 is an infrared-based detection sensor. Here, the camera may be a camera lens or an image sensor.

In the case that the first electronic device 11 is a camera, the camera may be located behind (i.e., below) the display panel 110, but may be a front camera for photographing the front direction of the display panel 110. Accordingly, the user may view a viewing surface of the display panel 110 and take pictures or self-photographs using a camera which is not visible to the viewing surface.

The normal area NA and one or more optical areas OA1 and OA2 may be areas capable of displaying an image. However, the normal area NA may be an area in which a light transmission structure does not need to be formed, and one or more optical areas OA1 and OA2 may be areas in which a light transmission structure is required to be formed.

Therefore, one or more optical areas OA1 and OA2 are required to have transmittance above a specific level, and the normal area NA may not have light transmittance or may have low transmittance below a specific level.

For example, one or more optical areas OA1 and OA2 and the normal area NA may have different resolutions, subpixel arrangement structures, number of subpixels per unit area, electrode structures, line structures, electrode arrangement structures, or line arrangement structures etc.

For example, the number of subpixels per unit area in one or more optical areas OA1 and OA2 may be smaller than the number of subpixels per unit area in the normal area NA. That is, the resolution of one or more optical areas OA1 and OA2 may be lower than the resolution of the normal area NA. Here, the number of subpixels per unit area may mean the same as resolution, pixel density, or pixel integration. For example, a unit of the number of subpixels per unit area may be PPI (Pixels Per Inch), which means the number of pixels in 1 inch.

For example, the number of subpixels per unit area in the first optical area OA1 may be less than the number of subpixels per unit area in the normal area NA. The number of subpixels per unit area in the second optical area OA2 may be greater than or equal to the number of subpixels per unit area in the first optical area OA1, and may be less than the number of subpixels per unit area in the normal area NA.

Meanwhile, as a method to increase the transmittance of at least one of the first optical area OA1 and the second optical area OA2, there may be applied a differential pixel density design method, as described above. According to the differential pixel density design method, the display panel 110 may be designed so as for the number of subpixels per unit area of at least one of the first optical area OA1 and the second optical area OA2 to be less than the number of subpixels per unit area of the normal area NA.

However, in some cases, a differential pixel size design method may be applied as another method to increase the transmittance of at least one of the first optical area OA1 and the second optical area OA2. According to the differential pixel size design method, the display panel 110 may be designed so as for the number of subpixels per unit area of at least one of the first optical area OA1 and the second optical area OA2 to be the same as or similar to the number of subpixels per unit area of the normal area NA, but so as for a size of each subpixel SP (i.e., the size of the emission area) disposed in at least one of the first optical area OA1 and the second optical area OA2 to be smaller than the size of each subpixel SP (i.e., the size of the emission area) placed in the normal area NA.

The first optical area OA1 may have various shapes such as circular, oval, square, hexagon, or octagon. The second optical area OA2 may have various shapes, such as circular, oval, square, hexagon, or octagon. The first optical area OA1 and the second optical area OA2 may have the same shape or different shapes.

Referring to FIG. 1C, in the case that the first optical area OA1 and the second optical area OA2 are in contact, the entire optical area including the first optical area OA1 and the second optical area OA2 may also have various shapes, such as circular, oval, square, hexagon, or octagon.

In the display device 100 according to the embodiments of the present disclosure, if the first electronic device 11, which is not exposed to the outside and is hidden at the bottom of the display panel 110, is a camera, a display device 100 according to embodiments of the present disclosure may be referred as a display device to which under display camera UDC technology is applied.

Accordingly, in the display device 100 according to embodiments of the present disclosure, there may not be required to be formed a notch or camera hole for camera exposure in the display panel 110, so that there is no reduction in area of the display area DA. Accordingly, the size of the bezel area may be reduced, design restrictions may be eliminated, and the degree of freedom in design may be increased.

In the display device 100 according to embodiments of the present disclosure, although the one or more electronic devices 11 and 12 are hidden behind the display panel 110, the one or more electronic devices 11 and 12 are required to be able to receive light normally and normally perform a designated function thereof.

In addition, in the display device 100 according to embodiments of the present disclosure, although the one or more electronic devices 11 and 12 are hidden behind the display panel 110 and are located overlapping with the display area DA, there is required that the normal image display function is possible in one or more optical areas OA1 and OA2 overlapping with one or more electronic devices 11 and 12 in the display area DA.

The first optical area OA1 and the second optical area OA2 may correspond to or be included in the first display area DA1 through which light can be transmitted, and the normal area NA may correspond to the second display area DA2 through which light is not transmitted, or may be included in the second display area DA2.

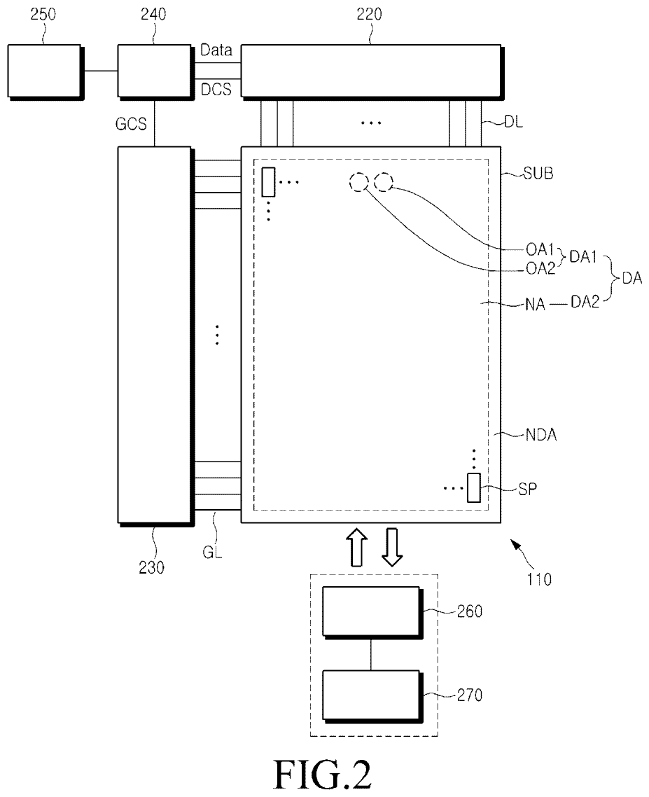

FIG. 2 illustrates a system configuration diagram of a display device 100 according to embodiments of the present disclosure.

Referring to FIG. 2, the display device 100 may include a display panel 110 and a display driving circuit as components for displaying an image.

The display driving circuit may be a circuit for driving the display panel 110, and may include a data driving circuit 220, a gate driving circuit 230 and a display controller 240.

The display panel 110 may include a display area DA for displaying an image and a non-display area NDA where an image is not displayed. The non-display area NDA may be an area outside the display area DA, and may also be referred to as a bezel area. All or part of the non-display area NDA may be an area visible from the front of the display device 100, or may be an area which is bent and not visible from the front of the display device 100.

The display panel 110 may include a substrate SUB and a plurality of subpixels SP disposed on the substrate SUB. Additionally, the display panel 110 may further include various types of signal lines to drive the plurality of subpixels SP.

The display device 100 according to embodiments of the present disclosure may be a liquid crystal display device or the like, or may be a self-luminous display device in which the display panel 110 emits light on its own. When the display device 100 according to embodiments of the present disclosure is a self-luminous display device, each of the plurality of subpixels SP may include a light emitting device. For example, the display device 100 according to embodiments of the present disclosure may be an organic light emitting display device in which a light emitting device is implemented as an organic light emitting diode (OLED). For another example, the display device 100 according to embodiments of the present disclosure may be an inorganic light emitting display device in which the light emitting device is implemented as an inorganic-based light emitting diode. For another example, the display device 100 according to embodiments of the present disclosure may be a quantum dot display device in which a light emitting device is implemented with quantum dots, which are self-luminous semiconductor crystals.

The structure of each of the plurality of subpixels SP may vary depending on the type of the display device 100. For example, if the display device 100 is a self-luminous display device in which subpixels SP emit light by themselves, each subpixel SP may include a light emitting device emitting light by itself, one or more transistors, and one or more capacitors.

For example, various types of signal lines may include a plurality of data lines DL transmitting data signals (also called data voltages or image signals) and a plurality of gate lines GL transmitting gate signals (also called scan signals).

The plurality of data lines DL and the plurality of gate lines GL may cross each other. Each of the plurality of data lines DL may be arranged to extend in a first direction. Each of the plurality of gate lines GL may be arranged to extend in a second direction. Here, the first direction may be a column direction and the second direction may be a row direction. Alternatively, the first direction may be a row direction and the second direction may be a column direction.

The data driving circuit 220 is a circuit for driving a plurality of data lines DL, and may output data signals to the plurality of data lines DL. The gate driving circuit 230 is a circuit for driving a plurality of gate lines GL, and may output gate signals to the plurality of gate lines GL.

The display controller 240 may be a device for controlling the data driving circuit 220 and the gate driving circuit 230, and may control the driving timing for the plurality of data lines DL and the driving timing of the plurality of gate lines GL.

The display controller 240 may supply a data driving control signal DCS to the data driving circuit 220 to control the data driving circuit 220, and may supply a gate driving control signal GCS to the gate driving circuit 230 to control the gate driving circuit 230.

The display controller 240 may receive input image data from a host system 250 and supply image data to the data driving circuit 220 based on the input image data.

The data driving circuit 220 may receive image data in digital form from the display controller 240 and convert the received image data into analog data signals to output to a plurality of data lines DL.

The gate driving circuit 230 may receive a first gate voltage corresponding to the turn-on level voltage and a second gate voltage corresponding to the turn-off level voltage along with various gate driving control signals GCS, and may generate gate signals and supply the generated gate signals to the plurality of gate lines GL.

For example, the data driving circuit 220 may be connected to the display panel 110 using a tape automated bonding (TAB) method, or may be connected to the bonding pad of the display panel 110 using a chip-on-glass (COG) or chip-on-panel (COP) method, or may be implemented using a chip-on-film (COF) method and connected to the display panel 110.

The gate driving circuit 230 may be connected to the display panel 110 using a tape automated bonding (TAB) method, or may be connected to the bonding pad of the display panel 110 using a chip-on-glass (COG) or chip-on-panel (COP) method, or may be implemented using a chip-on-film (COF) method and connected to the display panel 110. Alternatively, the gate driving circuit 230 may be a gate-in-panel (GIP) type and may be formed in the non-display area NDA of the display panel 110. The gate driving circuit 230 may be disposed on or connected to the substrate. That is, if the gate driving circuit 230 is a GIP type, the gate driving circuit 230 may be disposed in the non-display area NDA of the substrate. The gate driving circuit 230 may be connected to the substrate if the gate driving circuit 230 is a chip-on-glass (COG) type, a chip-on-film (COF) type, etc.

Meanwhile, at least one of the data driving circuit 220 and the gate driving circuit 230 may be disposed in the display area DA of the display panel 110. For example, at least one of the data driving circuit 220 and the gate driving circuit 230 may be arranged not to overlap the subpixels SP, or may be arranged to partially or entirely overlap with the subpixels SP.

The data driving circuit 220 may be connected to one side (e.g., the upper or lower side) of the display panel 110. Depending on the driving method, panel design method, etc., the data driving circuit 220 may be connected to both sides (e.g., upper and lower sides) of the display panel 110, or may be connected to two or more of the four sides of the display panel 110.

The gate driving circuit 230 may be connected to one side (e.g., left or right side) of the display panel 110. Depending on the driving method, panel design method, etc., the gate driving circuit 230 may be connected to both sides (e.g., left and right side) of the display panel 110, or may be connected to two or more of the four sides of the display panel 110.

The display controller 240 may be implemented as a separate component from the data driving circuit 220, or may be integrated with the data driving circuit 220 and implemented as an integrated circuit.

In order to provide not only an image display function but also a touch sensing function, the display device 100 according to embodiments of the present disclosure may include a touch sensor and a touch sensing circuit for detecting an occurrence of a touch by a touch object such as a finger or pen or for detecting a touch position by sensing the touch sensor.

The touch sensing circuit may include a touch driving circuit 260 for driving and sensing a touch sensor to generate and output touch sensing data, and a touch controller 270 for detecting the occurrence of a touch or detecting the touch position using touch sensing data.

The touch sensor may include a plurality of touch electrodes. The touch sensor may further include a plurality of touch lines to electrically connect a plurality of touch electrodes and the touch driving circuit 260.

The touch sensor may exist outside the display panel 110 in the form of a touch panel or may exist inside the display panel 110.

If the touch sensor exists inside the display panel 110, the touch sensor may be formed on the substrate SUB along with signal lines and electrodes related to display driving during the manufacturing process of the display panel 110.

The touch driving circuit 260 may supply a touch driving signal to at least one of the plurality of touch electrodes and generate touch sensing data by sensing at least one of the plurality of touch electrodes.

The touch sensing circuit may perform touch sensing using a self-capacitance sensing method or a mutual-capacitance sensing method.

The touch driving circuit 260 and the touch controller 270 included in the touch sensing circuit may be implemented as separate devices or as one device. Additionally, the touch driving circuit 260 and the data driving circuit 220 may be implemented as separate devices or as one device.

The display device 100 according to embodiments of the present disclosure may be a mobile terminal such as a smart phone or tablet, or a monitor or television of various sizes, but is not limited thereto, and may be a display of various types and sizes capable of displaying information or images.

In the display panel 110, the display area DA may include a first display area DA1 and a second display area DA2, and the first display area DA1 may include at least one of a first optical area OA1 and a second optical area OA2, and the second display area DA2 may include a normal area NA.

Both the first display area DA1 and the second display area DA2 are areas capable of displaying images. However, the second display area DA2 is an area in which a light transmission structure does not need to be formed, and the first display area DA1 is an area in which a light transmission structure needs to be formed. Hereinafter, the first optical area OA1 or the second optical area OA2 may be referred to as the first display area DA1, and the normal area NA may be referred to as the second display area DA2.

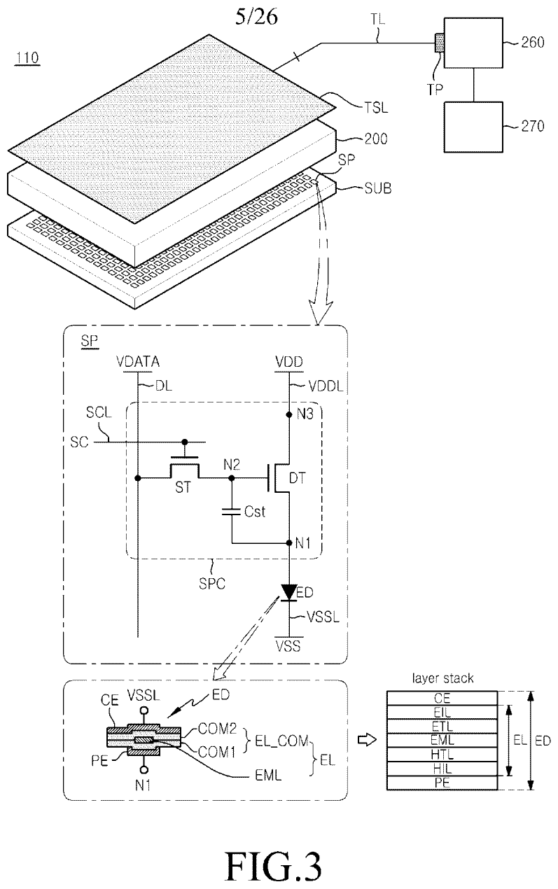

FIG. 3 illustrates a display panel 110 according to embodiments of the present disclosure.

Referring to FIG. 3, a plurality of subpixels SP may be disposed in the display area DA of the display panel 110. A plurality of subpixels SP may be disposed in the normal area NA, the first optical area OA1, and the second optical area OA2 included in the display area DA.

Referring to FIG. 3, each of the plurality of subpixels SP may include a light emitting device ED and a subpixel circuit SPC configured to drive the light emitting device ED.

Referring to FIG. 3, the subpixel circuit SPC may include a driving transistor DT for driving the light emitting device ED, a scan transistor ST for transferring the data voltage Vdata to the driving transistor DT, and a storage capacitor Cst for maintaining a constant voltage during one frame.

The driving transistor DT may include a first node N1, a second node N2, and a third node N3. The first node N1 may be a node which is electrically connected to the light emitting device ED. The second node N2 may be a node which is connected to the scan transistor ST. The third node N3 may be a node which is connected to a driving voltage line VDDL. The first node N1 may be electrically connected to the pixel electrode PE of the light emitting device ED. The data voltage VDATA may be applied to the second node N2. A driving voltage VDD may be applied to the third node N3. The first node N1 may be a source node or a drain node, the second node N2 may be a gate node, and the third node N3 may be a drain node or a source node. Hereinafter, for convenience of explanation, in the driving transistor DT, it will be exemplified a case in which the first node N1 is a source node, the second node N2 is a gate node, and the third node N3 is a drain node.

The light emitting device ED may include a pixel electrode PE, an intermediate layer EL, and a common electrode CE. The pixel electrode PE may be an electrode disposed in each subpixel SP. For example, the pixel electrode PE may be electrically connected directly or indirectly (via another transistor) to the first node N1 of the driving transistor DT of each subpixel SP. The common electrode CE may be an electrode commonly disposed in the plurality of subpixels SP. For example, the common electrode CE may be electrically connected to a base voltage line VSSL. A base voltage VSS, which is a type of common driving voltage, may be applied to the common electrode CE through the base voltage line VSSL. For example, the pixel electrode PE may be an anode electrode, and the common electrode CE may be a cathode electrode. Alternatively, the pixel electrode PE may be a cathode electrode, and the common electrode CE may be an anode electrode. Hereinafter, for convenience of explanation, it is assumed that the pixel electrode PE is an anode electrode and the common electrode CE is a cathode electrode.

The intermediate layer EL may include an emission layer EML and a common intermediate layer EL_COM.

The emission layer EML may be disposed in an emission area of each of the plurality of subpixels SP. For example, the emission layer EML may be disposed only in each of the plurality of subpixels SP. As another example, the emission layer EML may be commonly disposed in a plurality of subpixels SP. As another example, the emission layer EML may be disposed only in the emission area. As another example, the emission layer EML may be disposed in both the emission area and a non-emission area.

The common intermediate layer EL_COM may be commonly disposed across a plurality of subpixels SP. The common intermediate layer EL_COM may be commonly disposed over a plurality of emission areas EA and non-emission areas.

The common intermediate layer EL_COM may include a first common intermediate layer COM1 and a second common intermediate layer COM2. The first common intermediate layer COM1 may be disposed between the pixel electrode PE and the emission layer EML, and may include at least one layer (e.g., an organic layer).

For example, the first common intermediate layer COM1 may include a hole injection layer HIL and a hole transfer layer HTL. The second common intermediate layer COM2 may include an electron transport layer ETL, an electron injection layer EIL, and the like. The hole injection layer HIL may inject holes from the pixel electrode PE to the hole transport layer, the hole transport layer HTL may transport holes to the emission layer EML, and the electron injection layer EIL may inject electrons from the common electrode CE to the electron transport layer, and the electron transport layer ETL may transport electrons to the emission layer EML.

Each light emitting device ED may include an overlapping portion of a pixel electrode PE (or first electrode), an emission layer EML in the intermediate layer EL, and a common electrode (or second electrode) CE. A predetermined emission area EA may be formed by each light emitting device ED. For example, the emission area EA may be defined as an area where the pixel electrode PE, the emission layer EML in the intermediate layer EL, and the common electrode CE overlap. For example, the light emitting device ED may be an organic light emitting diode (OLED) based on organic materials, an inorganic light emitting diode based on inorganic materials, or a quantum dot light emitting device. in the case that the light emitting device ED is an organic light emitting diode, the intermediate layer EL in the light emitting device ED may include an organic layer containing an organic material.

The scan transistor ST may be controlled on-off by a scan signal SC as a type of gate signal applied through the scan signal line SCL as a type of gate line GL, and may be electrically connected between the second node N2 of the driving transistor DT and the data line DL.

The storage capacitor Cst may be electrically connected between the first node N1 and the second node N2 of the driving transistor DT.

The subpixel circuit SPC may have a 2T (Transistor)-1C (Capacitor) structure including two transistors DT and ST and one capacitor Cst, as shown in FIG. 3, and may further include one or more transistors or one or more capacitors in some case.

The storage capacitor Cst may be an external capacitor intentionally designed outside the driving transistor DT rather than a parasitic capacitor (e.g., Cgs, Cgd) as an internal capacitor which may exist between the first node N1 and the second node N2 of the driving transistor DT. Each of the driving transistor DT and the scan transistor ST may be an n-type transistor or a p-type transistor.

The circuit elements within each subpixel SP (in particular, light emitting devices EDs implemented with organic light emitting diodes (OLEDs) containing organic materials) may be vulnerable to external moisture or oxygen. Therefore, there may be disposed an encapsulation layer 200 on the display panel 110 to prevent oxygen from penetrating into the circuit elements (particularly, the light emitting device ED. The encapsulation layer 200 may be disposed to cover the light emitting devices ED.

Referring to FIG. 3, the display device 100 according to embodiments of the present disclosure may include, in order to sense the user's touch, a touch sensor layer TSL including a plurality of sensor electrodes, a touch driving circuit 260 configured to sense a plurality of sensor electrodes, and a touch controller 270 configured to determine the presence or absence of a touch or touch coordinates using the sensing result (i.e., touch sensing data) of the touch driving circuit 260.

The touch sensor layer TSL may be embedded into the display panel 110. For example, the touch sensor layer TSL may be disposed on the encapsulation layer 200 within the display panel 110.

The display panel 110 may further include a plurality of touch pads TP electrically connected to the touch driving circuit 260, and a plurality of touch routing lines for electrically connecting a plurality of sensor electrodes included in the touch sensor layer TSL to a plurality of touch pads TP connected to the touch driving circuit 260.

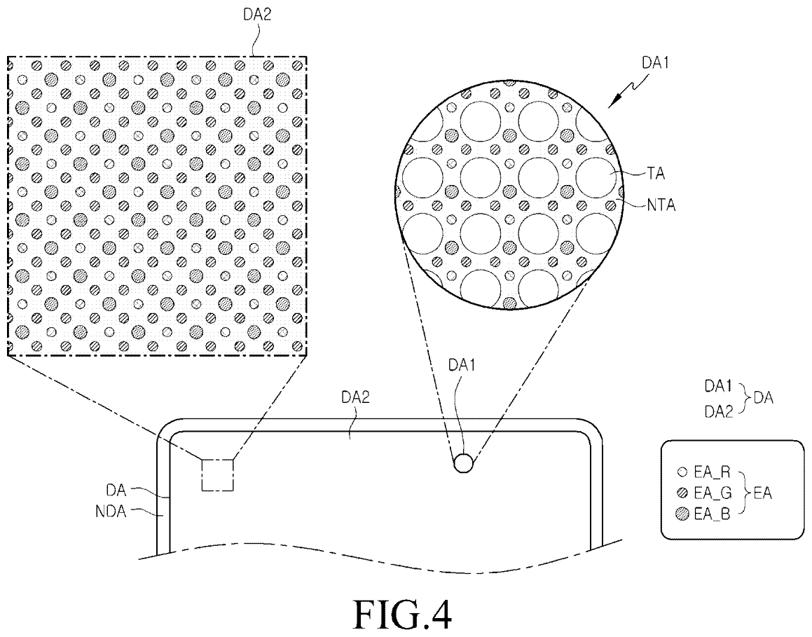

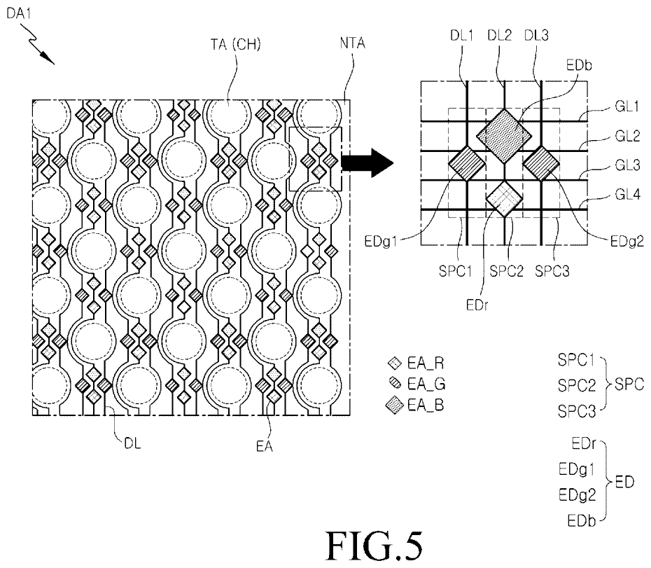

FIG. 4 illustrates a first display area DA1 of a first type and a second display area DA2 outside a first display area in a display panel 110 according to embodiments of the present disclosure. FIG. 5 is a plan view of a first display area DA1 of a first type in a display panel 110 according to embodiments of the present disclosure.

Referring to FIG. 4, the display panel 110 according to embodiments of the present disclosure may include a display area DA where an image is displayed and a non-display area NDA where an image is not displayed.

Referring to FIG. 4, the display area DA may include a first display area DA1 and a second display area DA2 outside the first display area DA1.

The first display area DA1 may include a plurality of transmission areas TA and a non-transmission area NTA excluding the plurality of transmission areas TA. The non-transmission area NTA may include a plurality of emission areas EA. The non-transmission area NTA may include a plurality of light emitting device ED to form a plurality of emission areas EA and a plurality of subpixel circuits SPC to drive the plurality of light emitting devices ED. The plurality of light emitting devices ED and the plurality of subpixel circuits SPC may partially overlap each other.

The first display area DA1 may include a plurality of transmission areas TA and a plurality of emission areas EA, and may be an area where a plurality of subpixel circuits SPC may also be disposed. In this case, the first display area DA1 may be referred to have a first type structure. Here, the first type may be also referred to as a hole type.

As an example, the non-transmission area NTA in the first display area DA1 may be an area through which light does not transmit. The second display area DA2 may also be an area where light does not transmit.

As another example, the non-transmission area NTA in the first display area DA1 may be an area with a significantly low transmittance. In the first display area DA1, the transmittance of the non-transmission area NTA may be lower than the transmittance of the transmission area TA. However, the transmittance of the non-transmission area NTA in the first display area DA1 may be higher than the transmittance of the second display area DA2.

The display area DA may include a plurality of light emission areas or emission areas EA. Since the first display area DA1 and the second display area DA2 are areas included in the display area DA, each of the first display area DA1 and the second display area DA2 may include a plurality of emission areas EA.

The arrangement of the emission areas EA in the first display area DA1 may be the same as the arrangement of the emission areas EA in the second display area DA2.

The area of each of the plurality of emission areas EA included in the first display area DA1 may be the same as the area of each of the plurality of emission areas EA included in the second display area DA2, or may be different from the area of each of the plurality of emission areas EA included in the second display area DA2 within a predetermined range.

For example, the plurality of emission areas EA disposed in each of the first display area DA1 and the second display area DA2 may include a first color emission area emitting light of a first color, a second color emission area emitting light of a second colors, and a third color emission area emitting light of a third color. At least one of the first color emission area, the second color emission area, and the third color emission area may have an area different from the others. The first color, second color, and third color are different colors, and may be various colors. For example, the first color, second color, and third color may include red, green, and blue. Hereinafter, for convenience of explanation, it will be exemplified a case in which the first color is red, the second color is green, and the third color is blue, however, is not limited thereto. For example, in the case that the first color is red, the second color is green, and the third color is blue, the area of a blue emission area EA_B may be the largest among the area of a red emission area EA_R, the area of a green emission area EA_G, and the area of a blue emission area EA_B.

Among the emission layer EML emitting red light, the emission layer EML emitting green light and the emission layer EML emitting blue light, an organic material contained in the emission layer EML emitting blue light may be the most susceptible to material deterioration.

The current density supplied to the light emitting device ED disposed in the blue emission area EA_B can be the lowest by designing the area of the blue emission area EA_B to be the largest. Therefore, the degree of deterioration of a light emitting device ED disposed in the blue emission area EA_B may be similar to the degree of deterioration of a light emitting device ED disposed in the red emission area EA_R and a light emitting device ED disposed in the green emission area EA_G.

Therefore, there may be eliminated or reduced the deterioration variation between the light emitting device ED disposed in the red emission area EA_R, the light emitting device ED disposed in the green emission area EA_G and the light emitting device ED disposed in the blue emission area EA_B, thereby improving image quality. In addition, since there may be eliminated or reduced the deterioration variation between the light emitting device ED disposed in the red emission area EA_R, the light emitting device ED disposed in the green emission area EA_G and the light emitting device ED disposed in the blue emission area EA_B, there may provide an effect of reducing the lifespan variation between the light emitting device ED disposed in the red emission area EA_R, the light emitting device ED disposed in the green emission area EA_G and the light emitting device ED disposed in the blue emission area EA_B.

The common electrode CE is commonly disposed in the second display area DA2 and the first display area DA1, but may include a plurality of common electrode holes CH in the first display area DA1. The plurality of common electrode holes CH may correspond to the plurality of transmission areas TA in the first display area DA1.

Since the first display area DA1 includes a plurality of transmission areas TA, the first display area DA1 may have a higher transmittance than the transmittance of the second display area DA2.

All or part of the first display area DA1 may overlap with an electronic device. The electronic device overlapping the first display area DA1 may be a first electronic device 11 and/or a second electronic device 12.

Referring to FIG. 5, in the case of a first display area DA1 of a first type, the data lines DL1, DL2, and DL3 and the gate lines GL1, GL2, GL3, and GL4 may pass through the first display area DA1.

For example, within the first display area DA1, the data lines DL1, DL2, and DL3 may be arranged in a column direction (or row direction) while avoiding the transmission area TA corresponding to the common electrode hole CH. As another example, within the first display area DA1, the data lines DL1, DL2, and DL3 may be arranged in the column direction (or row direction) while passing through the transmission area TA corresponding to the common electrode hole CH. In this case, the line part passing through the transmission area TA in each of the data lines DL1, DL2, and DL3 may be made of transparent metal.

For example, within the first display area DA1, the gate lines GL1, GL2, GL3, and GL4 may be arranged in a column direction (or row direction) while avoiding the transmission area TA corresponding to the common electrode hole CH. As another example, within the first display area DA1, the gate lines GL1, GL2, GL3, and GL4 may be arranged in the column direction (or row direction) while passing through the transmission area TA corresponding to the common electrode hole CH. In this case, the line part passing through the transmission area TA in each of the gate lines GL1, GL2, GL3, and GL4 may be made of transparent metal.

For example, the transparent metal may include transparent conductive oxide (TCO). For example, transparent conductive oxide (TCO) may include at least one of indium zinc oxide (IZO), indium tin oxide (ITO), indium-gallium-zinc oxide (IGZO), zinc oxide (ZnO), aluminum-doped zinc oxide (AZO), gallium-doped zinc oxide (GZO), antimony tin oxide (ATO), and fluorine-doped transparent oxides (FTO).

The data lines DL1, DL2, and DL3, and the gate lines GL1, GL2, GL3, and GLA may be connected to the subpixel circuits SPC1, SPC2 and SPC3 arranged in the first display area DA1.

For example, four light emitting devices EDr, EDg1, EDg2 and EDb may be disposed in a non-transmission area NTA between four adjacent transmission areas TA. The four light emitting devices EDr, EDg1, EDg2 and EDb may include one red light emitting device EDr, two green light emitting devices EDg1 and EDg2, and one blue light-emitting device EDb.

For example, a subpixel circuit SPC1 for driving one red light emitting device EDr may be connected to a first data line DL1 and a first gate line GL1. A subpixel circuit SPC2 for driving the two green light emitting devices EDg1 and EDg2 may be connected to a second data line DL2, a second gate line GL2, and a third gate line GL3. A subpixel circuit SPC3 for driving one blue light emitting device EDb may be connected to a third data line DL3 and a fourth gate line GL4.

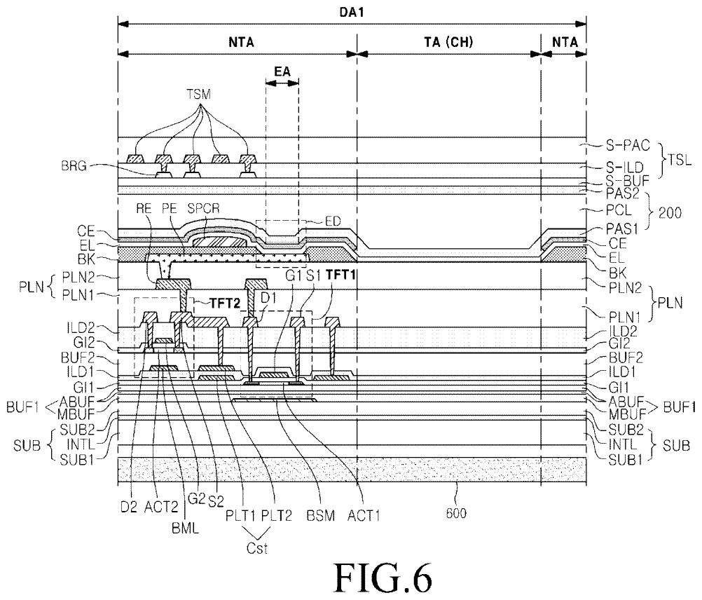

FIG. 6 is a cross-sectional view of a first display area of a first type in a display panel according to embodiments of the present disclosure.

Referring to FIG. 6, the display panel 110 may include a transistor forming part, a light emitting device forming part, an encapsulation part, and a touch sensor.

The transistor forming part may include a substrate SUB, a first buffer layer BUF1 on the substrate SUB, a plurality of transistors TFT1 and TFT2 formed on the first buffer layer BUF, a storage capacitor Cst, and various electrodes or signal lines.

The substrate SUB may include a first substrate SUB1 and a second substrate SUB2, and may include a substrate intermediate layer INTL between the first substrate SUB1 and the second substrate SUB2. Here, for example, the substrate intermediate layer INTL may be an inorganic layer and may block moisture penetration.

A lower shield metal BSM may be disposed on the substrate SUB. The lower shield metal BSM may be located below a first active layer ACT1 of a first transistor TFT1.

The first buffer layer BUF1 may be a single layer or a multi-layer. if the first buffer layer BUF1 is a multi-layer, the first buffer layer BUF1 may include a multi-buffer layer MBUF and an active buffer layer ABUF.

Various transistors TFT1 and TFT2, a storage capacitor Cst, and various electrodes or signal lines may be formed on the first buffer layer BUF1.

For example, the transistors TFT1 and TFT2 formed on the first buffer layer BUF1 may be made of the same material and located in the same layers. Alternatively, as shown in FIG. 6, a first transistor TFT1 and a second transistor TFT2 among the transistors TFT1 and TFT2 may be made of different materials, and may be located in different layers.

The first transistor TFT1 may include a first active layer ACT1, a first gate electrode G1, a first source electrode S1, and a first drain electrode D1. The second transistor TFT2 may include a second active layer ACT2, a second gate electrode G2, a second source electrode S2, and a second drain electrode D2.

The second active layer ACT2 of the second transistor TFT2 may be located higher than the first active layer ACT1 of the first transistor TFT1.

The first active layer ACT1 of the first transistor TFT1 and the second active layer ACT2 of the second transistor TFT2 may include different semiconductor materials. For example, the first active layer ACT1 of the first transistor TFT1 may include a semiconductor material different from the second active layer ACT2 of the second transistor TFT2. For example, the first active layer ACT1 of the first transistor TFT1 may include a silicon-based semiconductor material. For example, the silicon-based semiconductor material may include low-temperature polycrystalline silicon (LTPS). For example, the second active layer ACT2 of the second transistor TFT2 may include an oxide semiconductor material. For example, oxide semiconductor materials may include indium gallium zinc oxide (IGZO), indium gallium zinc tin oxide (IGZTO), zinc oxide (ZnO), cadmium oxide (CdO), indium oxide (InO), zinc tin oxide (ZTO) or zinc indium tin oxide (ZITO).

The first buffer layer BUF1 may be disposed below the first active layer ACT1 of the first transistor TFT1, and a second buffer layer BUF2 may be disposed below the second active layer ACT2 of the second transistor TFT2.

That is, the first active layer ACT1 of the first transistor TFT1 may be located on the first buffer layer BUF1, and the second active layer ACT2 of the second transistor TFT2 may be located on the second buffer layer BUF2. Here, the second buffer layer BUF2 may be located higher than the first buffer layer BUF1.

The first active layer ACT1 of the first transistor TFT1 may be disposed on the first buffer layer BUF1, and a first gate insulating layer may be disposed on the first active layer ACT1 of the first transistor TFT1. A first gate electrode G1 of the first transistor TFT1 may be disposed on the first gate insulating layer GI1, and a first interlayer insulating layer ILD1 may be disposed on the first gate electrode G1 of the first transistor TFT1.

The first active layer ACT1 of the first transistor TFT1 may include a first channel area overlapping the first gate electrode G1, a first source connection area located on one side of the first channel area, and a first drain connection area located on the other side of the first channel area.

The second buffer layer BUF2 may be disposed on the first interlayer insulating layer ILD1.

The second active layer ACT2 of the second transistor TFT2 may be disposed on the second buffer layer BUF2, and a second gate insulating layer GI2 may be disposed on the second active layer ACT2. A second gate electrode G2 of the second transistor TFT2 may be disposed on the second gate insulating layer GI2, and a second interlayer insulating layer ILD2 may be disposed on the second gate electrode G2.

The second active layer ACT2 of the second transistor TFT2 may include a second channel area overlapping the second gate electrode G2, a second source connection area located on one side of the second channel area, and a second drain connection area located on the other side of the second channel area.

A first source electrode S1 and a first drain electrode D1 of the first transistor TFT1 may be disposed on the second interlayer insulating layer ILD2. Additionally, a second source electrode S2 and a second drain electrode D2 of the second transistor TFT2 may be disposed on the second interlayer insulating layer ILD2.

The first source electrode S1 and the first drain electrode D1 of the first transistor TFT1 may be connected to the first source connection area and the first drain connection area of the first active layer ACT1, respectively, via the through holes of the second interlayer insulating layer ILD2, the second gate insulating layer GI2, the second buffer layer BUF2, the first interlayer insulating layer ILD1 and the first gate insulating layer GI1.

The second source electrode S2 and the second drain electrode D2 of the second transistor TFT2 may be connected to the second source connection area and the second drain connection area of the second active layer ACT2, respectively through the through holes in the second interlayer insulating layer ILD2 and the second gate insulating layer GI2.

The storage capacitor Cst may include a first capacitor electrode PLT1 and a second capacitor electrode PLT2.

The first capacitor electrode PLT1 may be electrically connected to the second gate electrode G2 of the second transistor TFT2, and the second capacitor electrode PLT2 may be electrically connected to the second source electrode S2 of the second transistor TFT2.

A lower metal BML may be disposed under the second active layer ACT2 of the second transistor TFT2. The lower metal BML may overlap with all or part of the second active layer ACT2.

For example, the lower metal BML may be electrically connected to the second gate electrode G2. As another example, the lower metal BML may serve as a light shield for blocking light coming from the lower part. In this case, the lower metal BML may be electrically connected to the second source electrode S2.

For example, the first transistor TFT1 may be a driving transistor for driving the light emitting device ED, and the second transistor TFT2 may be a scan transistor.

The display panel 110 may include a planarization layer PLN disposed on the first transistor TFT1 and the second transistor TFT2.

For example, the planarization layer PLN may include a first planarization layer PLN1. The first planarization layer PLN1 may be formed on the first source electrode S1 and the first drain electrode D1 of the first transistor TFT1 and the second source electrode S2 and the second drain electrode D2 of the second transistor TFT2.

A relay electrode RE may be disposed on the first planarization layer PLN1. The relay electrode RE may be an electrode for relaying the electrical connection between the second source electrode S2 of the transistor TFT2 and the pixel electrode PE of the light emitting device ED. The relay electrode RE may be electrically connected to the second source electrode S2 of the second transistor TFT2 through a hole in the first planarization layer PLN1.

The planarization layer PLN disposed on the display panel 110 may further include a second planarization layer PLN2 on the first planarization layer PLN1. For example, the second planarization layer PLN2 may be disposed while covering the relay electrode RE located on the first planarization layer PLN1.

Referring to FIG. 6, the light emitting device forming part may be located on the second planarization layer PNL2, and may further include a pixel electrode PE, intermediate layer EL, and common electrode CE for forming the light emitting device ED.

The light emitting device ED may be configured in an area where the pixel electrode PE, the intermediate layer EL, and the common electrode CE overlap.

The pixel electrode PE may be disposed on the second planarization layer PLN2. The pixel electrode PE may be connected to the relay electrode RE through a hole in the second planarization layer PLN2.

A bank BK may be disposed on the pixel electrode PE.

The bank BK may include a bank hole, and a portion of the pixel electrode PE may be exposed through the bank hole. That is, the bank hole formed in the bank BK may overlap a portion of the pixel electrode PE.

The intermediate layer EL may be disposed on the bank BK. The intermediate layer EL may contact a portion of the pixel electrode PE through the bank hole.

At least one spacer SPCR may be additionally disposed between the intermediate layer EL and the bank BK.

A common electrode CE may be disposed on the intermediate layer EL. The common electrode CE may include a common electrode hole CH. The common electrode hole CH formed in the common electrode CE may be disposed in the first display area DA1. One common electrode hole CH may exist between two adjacent emission areas EA.

Referring to FIG. 6, an encapsulation part may be located on the cathode electrode CE. The encapsulation part may include an encapsulation layer 200 formed on the cathode electrode CE.

The encapsulation layer 200 may be a layer which prevents moisture or oxygen from penetrating into the light emitting device ED. In particular, the encapsulation layer 200 may prevent moisture or oxygen from penetrating into the intermediate layer EL, which may include an organic layer. Here, the encapsulation layer 200 may be composed of a single layer or multiple layers.

The encapsulation layer 200 may include a first encapsulation layer PAS1, a second encapsulation layer PCL, and a third encapsulation layer PAS2. For example, the first encapsulation layer PAS1 and the third encapsulation layer PAS2 may be inorganic layers, and the second encapsulation layer PCL may be an organic layer. Since the second encapsulation layer PCL is composed of an organic layer, the second encapsulation layer PCL may function as a planarization layer.

The display panel 110 according to embodiments of the present disclosure may include a touch sensor layer TSL formed on the encapsulation layer 200. The touch sensor layer TSL may include touch sensor metals TSM and bridge metals BRG, and may further include one or more insulating layers such as a sensor buffer layer S-BUF, a sensor interlayer insulating layer S-ILD and a sensor protection layer S-PAC. Here, the sensor interlayer insulating layer S-ILD may be omitted.

The sensor buffer layer S-BUF may be disposed on the encapsulation layer 200. The bridge metals BRG may be disposed on the sensor buffer layer S-BUF, and the sensor interlayer insulating layer S-ILD may be disposed on the bridge metals BRG. Here, the sensor buffer layer S-BUF may be omitted.

Touch sensor metals TSM may be disposed on the sensor interlayer insulating layer S-ILD. Some of the touch sensor metals TSM may be connected to the corresponding bridge metal BRG through holes in the sensor interlayer insulating layer S-ILD.

The touch sensor metals TSM and bridge metals BRG may be disposed in the non-transmission area NTA in the first display area DA1. The touch sensor metals TSM and bridge metals BRG may not be disposed in the transmission area TA in the first display area DA1. The touch sensor metals TSM and bridge metals BRG may be arranged so as not to overlap the emission area EA in the non-transmission area NTA.

A plurality of touch sensor metals TSM may form one touch electrode (or one touch electrode line), and may be arranged in a mesh shape and electrically connected. A portion of the touch sensor metals TSM and another portion of the touch sensor metals TSM may be electrically connected through a bridge metal BRG to form one touch electrode (or one touch electrode line).

The sensor protection layer S-PAC may be disposed while covering the touch sensor metals TSM and bridge metals BRG.

At least a portion of the touch sensor metal TSM located on the encapsulation layer 200 in the display area DA may be extended and disposed along an outer inclined surface of the encapsulation layer 200 and electrically connected to a pad located further outside the outer inclined surface of the encapsulation layer 200. Here, the pad may be disposed in the non-display area NDA and may be a metal pattern to which the touch driving circuit 260 is electrically connected.

In the transmission area TA, the common electrode CE may have a common electrode hole CH formed therein. That is, the common electrode hole CH may overlap the transmission area TA.

For example, in the transmission area TA, a hole may be formed in the bank BK. As another example, in the transmission area TA, a hole may not be formed in the bank BK. That is, there may be a hole in the bank BK which overlaps the transmission area TA.

At least a portion of the first display area DA1 may overlap an electronic device 600. The electronic device 600 may be a first electronic device 11 and/or a second electronic device 12.

The cross-sectional structure of the second display area DA2 may be the same as that of the non-transmission area NTA in the first display area DA1.

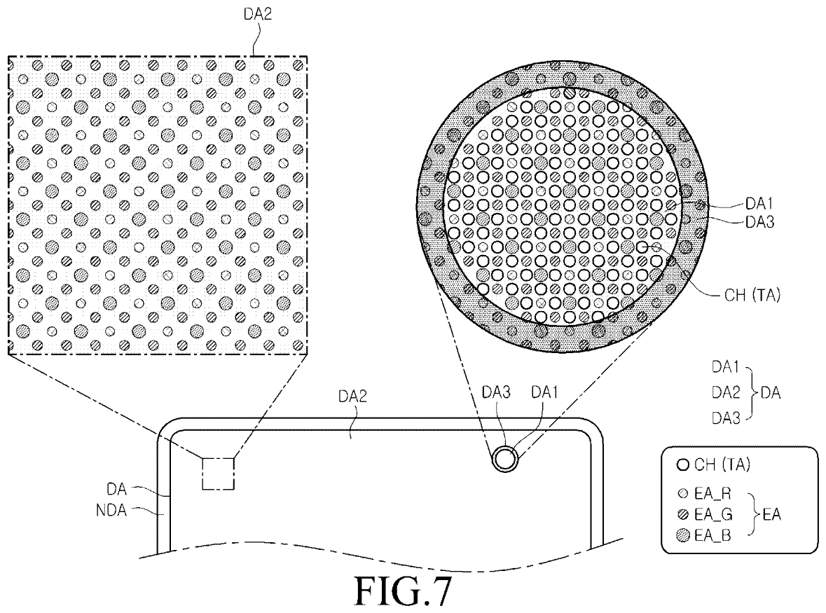

FIG. 7 illustrates a first display area DA1 of a second type, and a second display area DA2 and a third display area DA3 outside the first display area in a display panel 110 according to embodiments of the present disclosure.

Referring to FIG. 7, the display panel 110 according to embodiments of the present disclosure may include a display area DA where an image is displayed and a non-display area NDA where an image is not displayed.

Referring to FIG. 7, the display area DA may include a transmissive first display area DA1 and a second display area DA2 surrounding the first display area DA1. The first display area DA1 may have a second type of structure. In the case that the first display area DA1 is of the second type, the third display area DA3 may be disposed outside the first display area DA1. For example, the third display area DA3 may be located between the first display area DA1 and the second display area DA2. In embodiments of the present disclosure, the third display area DA3 may be considered as a part of the second display area DA2.

That is, if the first display area DA1 is the second type, the display area DA may include the first display area DA1, the second display area DA2 located outside the first display area DA1, and a third display area DA3 which is an area between the first display area DA1 and the second display area DA2.

The first display area DA1 may be an area which overlaps with an electronic device, and may be a transmission area through which light for the operation of the electronic device can be transmitted. Here, the light passing through the first display area DA1 may include light in a single wavelength band or light in various wavelength bands. For example, light passing through the first display area DA1 may include one or more of visible light and infrared light.

The electronic device may receive light passing through the first display area DA1 and perform a predetermined operation using the received light. Here, the light that the electronic device receives through the first display area DA1 may include at least one of visible light and infrared light.

Referring to FIG. 7, the third display area DA3 may be an area located outside the first display area DA1. The second display area DA2 may be an area located outside the third display area DA3. The third display area DA3 may be disposed between the first display area DA1 and the second display area DA2.

As an example, the third display area DA3 may be located on the outer edge of a portion of the first display area DA1. As another example, the third display area DA3 may be arranged outside the entire border of the first display area DA1.

In the case that the third display area DA3 is disposed outside the entire border of the first display area DA1, the third display area DA3 may have a ring shape surrounding the first display area DA1. For example, the first display area DA1 may have various shapes, such as circular, oval, polygonal, or irregular shapes. The third display area DA3 may have various ring shapes (e.g., a circular ring shape, an elliptical ring shape, a polygonal ring shape, or an irregular ring shape, etc.) surrounding the first display area DA1 having various shapes.

The display area DA may include a plurality of light emission areas EA. Since the first display area DA1, third display area DA3, and second display area DA2 are areas included in the display area DA, each of the first display area DA1, the third display area DA3 and second display areas DA2 may include a plurality of emission areas EA.

For example, the plurality of emission areas EA may include a first color emission area EA_R emitting light of a first color, a second color emission area EA_G emitting light of a second color, and a third color emission area EA_B emitting light of a third color.

Referring to FIG. 7, the first display area DA1 may be a transmission area, and is required to have high transmittance. Accordingly, the common electrode CE may include a plurality of common electrode holes CH in the first display area DA1. That is, in the first display area DA1, the common electrode CE may include a plurality of common electrode holes CH. In an embodiment, the common electrode CE may be formed with a plurality of opening areas in the transmission area TA to increase the transmittance.

Referring to FIG. 7, the common electrode CE may not include the common electrode hole CH in the second display area DA2. That is, in the second display area DA2, the common electrode CE may not include the common electrode hole CH.

In addition, the common electrode CE may not include the common electrode hole CH in the third display area DA3. That is, in the third display area DA3, the common electrode CE may not include the common electrode hole CH.

In the first display area DA1, a plurality of common electrode holes CH formed in the common electrode CE may also be referred to as a plurality of transmission areas TA or a plurality of openings. Here, in FIG. 7, one common electrode hole CH may have a circular shape, but in addition to the circular shape, the common electrode hole CH may have various shapes such as an elliptical shape, a polygonal shape, or an irregular shape.

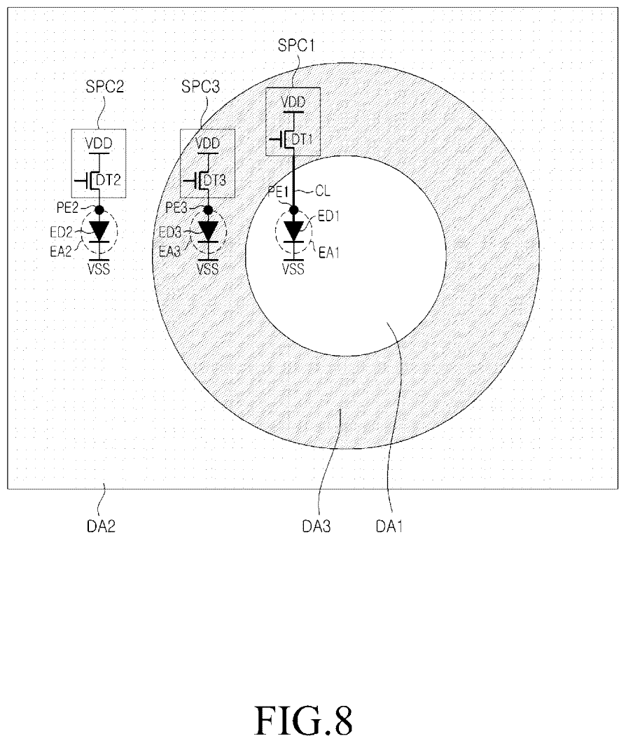

FIG. 8 illustrates first to third light emitting devices ED1, ED2 and ED3, and first to third subpixel circuits SPC1, SPC2 and SPC3 for driving the first to third light emitting devices ED1, ED2 and ED3.

Referring to FIG. 8, each of the first to third subpixel circuits SPC1, SPC2, and SPC3 may include a plurality of transistors DT and ST, and a storage capacitor Cst as shown in FIG. 3. However, for convenience of explanation, each of the first to third subpixel circuits SPC1, SPC2, and SPC3 is briefly represented as first to third driving transistors DT1, DT2 and DT3.

Referring to FIG. 8, subpixel circuits SPC1, SPC2 and SPC3 may be disposed in the third display area DA3 and the second display area DA2, but a subpixel circuit may be not disposed in the first display area DA1. That is, the transistors DT1, DT2 and DT3 may be disposed in the third display area DA3 and the second display area DA2, but the transistors may be not disposed in the first display area DA1.

The transistors DT and ST and storage capacitors Cst included in the subpixel circuits SPC1, SPC2 and SPC3 may be components capable of reducing transmittance. Accordingly, since the subpixel circuits SPC1, SPC2 and SPC3 are not disposed in the first display area DA1, the transmittance of the first display area DA1 may be further increased.

The subpixel circuits SPC1, SPC2 and SPC3 may be disposed in the second display area DA2 and the third display area DA3, but the light emitting devices ED1, ED2 and ED3 may be located in all of the first to third display areas DA1, DA2 and DA3.

A first light emitting device ED1 may be disposed in the first display area DA1, but the first subpixel circuit SPC1 for driving the first light emitting device ED1 may be not disposed in the first display area DA1.

Referring to FIG. 8, the first subpixel circuit SPC1 for driving the first light emitting device ED1 disposed in the first display area DA1 may be not disposed in the first display area DA1. Instead, the first subpixel circuit SPC1 may be placed in the third display area DA3.

Referring to FIG. 8, the plurality of emission areas EA included in the display panel 110 according to embodiments of the present disclosure may include a first emission area EA1, a second emission area EA2, and a third emission areas EA3.

The first emission area EA1 may be included in the first display area DA1, the second emission area EA2 may be included in the second display area DA2, and the third emission area EA3 may be included in the third display area DA3.

The display panel 110 according to embodiments of the present disclosure may include a first light emitting device ED1 disposed in the first display area DA1 and having a first emission area EA1, a second light emitting device ED2 disposed in the second display area DA2 and having a second emission area EA2, and a third light emitting device ED3 disposed in the third display area DA3 and having a third emission area EA3.

The display panel 110 according to embodiments of the present disclosure may include a first subpixel circuit SPC1 configured to drive the first light emitting device ED1, a second sub-pixel circuit SPC2 configured to drive the second light emitting device ED2, and a third subpixel circuit SPC3 configured to drive the third light emitting device ED3.

The first subpixel circuit SPC1 may include a first driving transistor DT1. The second subpixel circuit SPC2 may include a second driving transistor DT2. The third subpixel circuit SPC3 may include a third driving transistor DT3.

The first subpixel circuit SPC1 may be connected to a first pixel electrode PE1 of the first light emitting device ED1, and the second subpixel circuit SPC2 may be connected to a second pixel electrode PE2 of the second light emitting device ED2, and the third subpixel circuit SPC3 may be connected to a third pixel electrode PE3 of the third light emitting device ED3.

In the display panel 110 according to embodiments of the present disclosure, the second subpixel circuit SPC2 may be disposed in the second display area DA2 where the second light emitting device ED2 is disposed. The third subpixel circuit SPC3 may be disposed in the third display area DA3 where the third light emitting device ED3 is disposed.

The first subpixel circuit SPC1 for driving the first light emitting device ED1 may be not disposed in the first display area DA1 where the first light emitting device ED1 is disposed, and may be disposed in the third display area DA3 located outside the first display area DA1. Accordingly, the transmittance of the first display area DA1 may be increased.

The display panel 110 according to embodiments of the present disclosure may further include a connection line CL electrically connecting the first subpixel circuit SPC1 disposed in the third display area DA3 and the first light emitting device ED1 disposed in the first display area DA1.

The connection line CL may electrically extend the pixel electrode PE of the first light emitting device ED1 to the first node N1 of the first driving transistor DT1 in the first subpixel circuit SPC1.

The first subpixel circuit SPC1 for driving the first light-emitting device ED1 may be not disposed in the first display area DA1, and may disposed in the third display area DA3.

A structure in which the connection line CL connects the first pixel electrode PE1 of the first light emitting device ED1 in the first display area DA1 to the first subpixel circuit SPC1 in the third display area DA3 may be referred to a “pixel electrode extension structure.” If the pixel electrode is an anode electrode, the pixel electrode extension structure may also be referred to as an anode extension structure. Accordingly, the second type of the first display area DA1 may be also referred to as “a pixel electrode extension type” or “an anode extension type.”

If the display panel 110 according to embodiments of the present disclosure has a pixel electrode extension structure, all or part of the connection line CL may be disposed in the first display area DA1, and the connection line CL may include a transparent line. Accordingly, even if the connection line CL is disposed in the first display area DA1, there may be prevented a decrease in the transmittance of the first display area DA1.

The connection line CL may be made of transparent metal. For example, the transparent metal may include transparent conductive oxide (TCO). For example, transparent conductive oxides (TCOs) may include one or more of indium zinc oxide (IZO), indium tin oxide (ITO), indium-gallium-zinc oxide (IGZO), zinc oxide (ZnO), aluminum-doped zinc oxide (AZO), gallium-doped zinc oxide (GZO), antimony tin oxide (ATO), and fluorine-doped transparent oxides (FTO).

As described above, the first subpixel circuit SPC1 disposed in the third display area DA3 may drive one first light emitting device ED1 disposed in the first display area DA1. This driving method and circuit connection method may be called one-to-one (1:1) driving method and one-to-one (1:1) circuit connection method. Here, in this specification, the 1:1 driving method is used in the same sense as the 1:1 circuit connection method.

Accordingly, the number of subpixel circuits SPC1 and SPC3 disposed in the third display area DA3 may significantly increase. The structure of the third display area DA3 may become complicated and the aperture ratio (or light emission area) of the third display area DA3 may decrease.

In order to increase the aperture ratio (or light emission area) of the third display area DA3 despite having a pixel electrode extension structure (i.e., anode extension structure), the display device 100 according to embodiments of the present disclosure may have a 1:N (N is a natural number of 2 or more) driving method and a 1:N circuit connection method. Here, in this specification, the 1:N driving method may be used with the same meaning as the 1:N circuit connection method.

According to the 1:N driving method, the first subpixel circuit SPC1 disposed in the third display area DA3 may simultaneously operate two or more light emitting devices ED1 disposed in the first display area DA1.

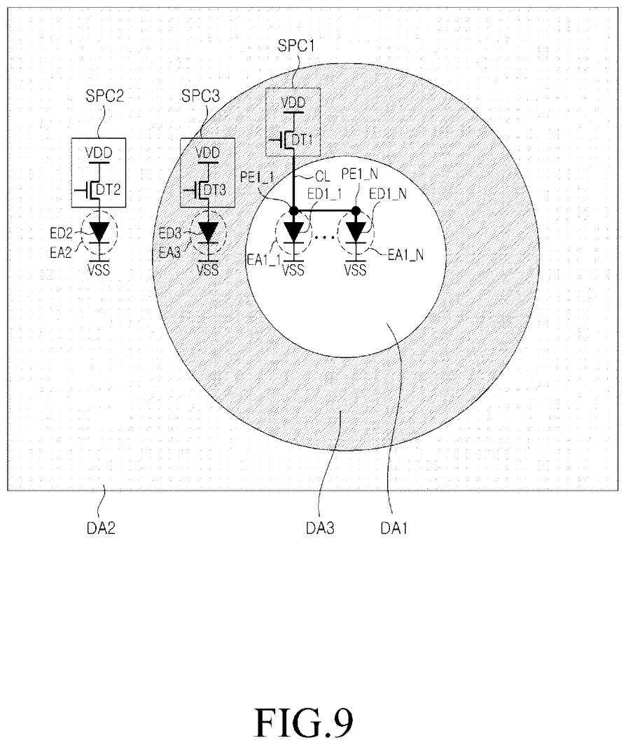

FIG. 9 illustrates the first to third light emitting devices ED1, ED2 and ED1_1˜ED1_N, and first to third subpixel circuits SPC1, SPC2 and SPC3 for driving the first to third light emitting devices ED1, ED2 and ED1_1˜ED1_N.

N first light emitting devices ED1_1 to ED1_N (N is a natural number of 2 or more) arranged in the first display area DA1 may be driven by one first subpixel circuit SPC1 arranged in the third display area DA3.

To this end, one first subpixel circuit SPC1 may be connected to N first pixel electrodes PE1_1 to PE1_N of N first light emitting devices ED1_1 to ED1_N. That is, the N first pixel electrodes PE1_1 to PE1_N of the N first light emitting devices ED1_1 to ED1_N may be electrically connected to each other.

Accordingly, although the display panel 110 has a pixel electrode extension structure (i.e., anode extension structure), the number of subpixel circuits SPC disposed in the third display area DA3 may be reduced, thereby increasing the openings and light emission area of the display area DA3.

N first light emitting devices ED1_1 to ED1_N driven together by one first subpixel circuit SPC1 may be light emitting device which emit light of the same color, and light emitting devices which are adjacent in the row or column direction. That is, the N first light emitting devices ED1_1 to ED1_N may be driven together by one first subpixel circuit SPC1 to form N first emission areas EA1_1 to EA1_N which emit light of the same color.

The connection line CL may connect one first subpixel circuit SPC1 disposed in the third display area DA3 to N first light emitting devices ED1_1 to ED1_N disposed in the first display area DA1.

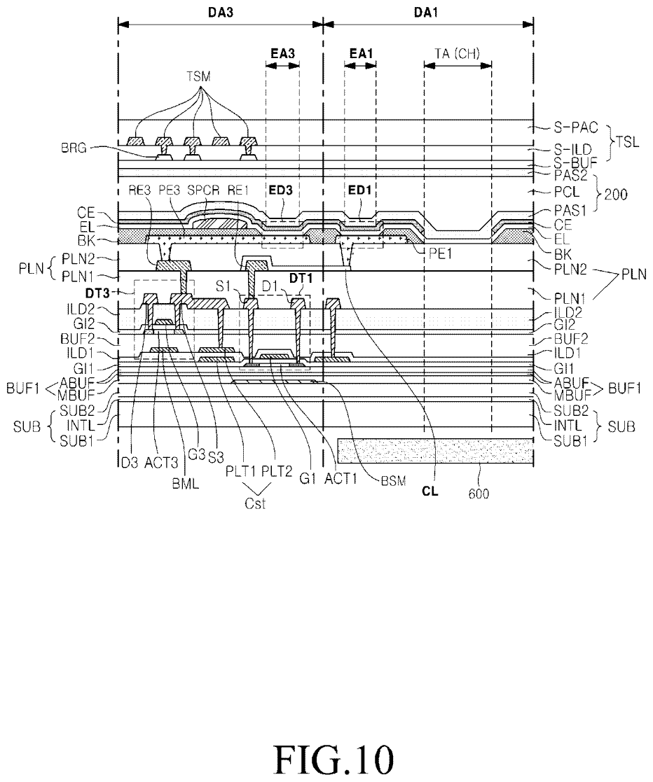

FIG. 10 is a cross-sectional view of the display panel 110 according to embodiments of the present disclosure, and is a cross-sectional view of the first display area DA1 and the third display area DA3 of the display panel 110. However, FIG. 10 is a cross-sectional view of the case of the 1:1 circuit connection method, as shown in FIG. 8. In addition, the stacked structure in FIG. 10 is the same as the stacked structure in FIG. 6. Accordingly, description of content corresponding to the stacked structure of FIG. 6 may be omitted.

Referring to FIG. 10, the display panel 110 may include a transistor forming part, a light emitting device forming part, an encapsulation part, and a touch sensor.

The transistor forming part may include a substrate SUB, a first buffer layer BUF on the substrate SUB, and various transistors DT1 and DT3 formed on the first buffer layer BUF, a storage capacitor Cst, and various electrodes or signal lines.

The substrate SUB may include a first substrate SUB1 and a second substrate SUB2, and may include a substrate intermediate layer INTL between the first substrate SUB1 and the second substrate SUB2. You can.

A lower shield metal BSM may be disposed on the substrate SUB. The lower shield metal BSM may be located below a first active layer ACT1 of a first driving transistor DT1.

A first buffer layer BUF1 may include a multi-buffer layer MBUF and an active buffer layer ABUF.

Various transistors DT1 and DT3, a storage capacitor Cst, and various electrodes or signal lines may be formed on the first buffer layer BUF1.

For example, the transistors DT1 and DT3 formed on the first buffer layer BUF1 may be made of the same material and may be located in the same layers. Alternatively, as shown in FIG. 10, a first driving transistor DT1 and a third driving transistor DT3 among the transistors DT1 and DT3 may be made of different materials and may be located in different layers.

The first driving transistor DT1 may be a driving transistor included in the first subpixel circuit SPC1 for driving the first light emitting device ED1 included in the first display area DA1, and the third driving transistor DT3 may be a driving transistor included in the third subpixel circuit SPC3 for driving the third light emitting device ED3 included in the third display area DA3.

The driving transistor DT1 may include a first active layer ACT1, a first gate electrode G1, a first source electrode S1, and a first drain electrode D1.

The third driving transistor DT3 may include a third active layer ACT3, a third gate electrode G3, a third source electrode S3, and a third drain electrode D3.

The third active layer ACT3 of the third driving transistor DT3 may be located higher than the first active layer ACT1 of the first driving transistor DT1.

A first buffer layer BUF1 may be disposed below the first active layer ACT1 of the first driving transistor DT1, and a second buffer layer BUF2 may be disposed below the third active layer ACT3 of the third driving transistor DT3.

That is, the first active layer ACT1 of the first driving transistor DT1 may be located on the first buffer layer BUF1, and the third active layer ACT3 of the third driving transistor DT3 may be located on the second buffer layer BUF2. Here, the second buffer layer BUF2 may be located higher than the first buffer layer BUF1.

The first active layer ACT1 of the first driving transistor DT1 may be disposed on the first buffer layer BUF1, and a first gate insulating layer GI1 may be disposed on the first active layer ACT1 of the first driving transistor DT1. The first gate electrode G1 of the first driving transistor DT1 may be disposed on the first gate insulating layer GI1, and a first interlayer insulating layer ILD1 may be disposed on the first gate electrode G1 of the first driving transistor DT1.

A second buffer layer BUF2 may be disposed on the first interlayer insulating layer ILD1. The third active layer ACT3 of the third driving transistor DT3 may be disposed on the second buffer layer BUF2, and a second gate insulating layer GI2 may be disposed on the third active layer ACT3. The third gate electrode G3 of the third driving transistor DT3 may be disposed on the second gate insulating layer GI2, and a second interlayer insulating layer ILD2 may be disposed on the third gate electrode G3.

The first source electrode S1 and the first drain electrode D1 of the first driving transistor DT1 may be disposed on the second interlayer insulating layer ILD2. Additionally, the third source electrode S3 and the third drain electrode D3 of the third driving transistor DT3 may be disposed on the second interlayer insulating layer ILD2.

The first source electrode S1 and the first drain electrode D1 of the first driving transistor DT1 may be connected to the first source connection area and the first drain connection area of the first active layer ACT1, respectively, through the through holes of the second interlayer insulating layer ILD2, the second gate insulating layer GI2, the second buffer layer BUF2, the first interlayer insulating layer ILD1 and the first gate insulating layer GI1.

The third source electrode S3 and the second drain electrode D2 of the third driving transistor DT3 may be connected to the second source connection area and the second drain connection area of the third active layer ACT3, respectively through the through holes of the second interlayer insulating layer ILD2 and the second gate insulating layer GI2.

In FIG. 10, it is illustrated only the first driving transistor DT1 and the storage capacitor Cst included in the third subpixel circuit SPC3, and other transistors are omitted. In FIG. 10, it is illustrated only the first driving transistor DT1 included in the first subpixel circuit SPC1, and other transistors and storage capacitors are omitted.

The storage capacitor Cst included in the third subpixel circuit SPC3 may include a first capacitor electrode PLT1 and a second capacitor electrode PLT2. The first capacitor electrode PLT1 may be electrically connected to the third gate electrode G3 of the third driving transistor DT3, and the second capacitor electrode PLT2 may be electrically connected to the third source electrode S3 of the third driving transistor DT3.

Meanwhile, a lower metal BML may be disposed under the third active layer ACT3 of the third driving transistor DT3. The lower metal BML may overlap with all or part of the third active layer ACT3. For example, the lower metal BML may be electrically connected to the third gate electrode G3. As another example, the lower metal BML may serve as a light shield for blocking light coming from the lower part. In this case, the lower metal BML may be electrically connected to the third source electrode S3.

The first driving transistor DT1 is a transistor for driving the first light emitting device ED1 disposed in the first display area DA1, but may be disposed in the third display area DA3. The third driving transistor DT3 is a transistor for driving the third light emitting device ED3 disposed in the third display area DA3, and may be disposed in the third display area DA3.

The display panel 110 may include at least one planarization layer PLN disposed on the first driving transistor DT1 and the third driving transistor DT3. For example, the planarization layer PLN may include a first planarization layer PLN1. The first planarization layer PLN1 may be disposed on the first source electrode S1 and the first drain electrode D1 of the first driving transistor DT1 and the third source electrode S3 and the third drain electrode D3 of the third driving transistor DT3.

Referring to FIG. 10, a first relay electrode RE1 and a third relay electrode RE3 may be disposed on the first planarization layer PLN1. The first relay electrode RE1 may be an electrode which relays the electrical connection between the first source electrode S1 of the first driving transistor DT1 and the first pixel electrode PE1 of the first light emitting device ED1. In addition, the third relay electrode RE3 may be an electrode which relays the electrical connection between the third source electrode S3 of the third driving transistor DT3 and the third pixel electrode PE3 of the third light emitting device ED3.

The first relay electrode RE1 may be electrically connected to the first source electrode S1 of the first driving transistor DT1 through a hole in the first planarization layer PLN1. The third relay electrode RE3 may be electrically connected to the third source electrode S3 of the third driving transistor DT3 through another hole in the first planarization layer PLN1.

The first relay electrode RE1 and the third relay electrode RE3 may be disposed in the third display area DA3.

Meanwhile, referring to FIG. 10, the display panel 110 may further include a connection line CL to electrically connect the first source electrode S1 of the first driving transistor DT1 disposed in the third display area DA3 and the first pixel electrode PE1 of the first light emitting device ED1 disposed in the first display area DA1.

The connection line CL may be connected to the first relay electrode RE1 and extend from the third display area DA3 to the first display area DA1. The connection line CL may extend to the first display area DA1 and be connected to the first pixel electrode PE1 disposed in the first display area DA1. The connection line CL may be a metal layer formed on the first relay electrode RE1, and may be made of a transparent material.

The planarization layer PLN disposed on the display panel 110 may further include a second planarization layer PLN2 on the first planarization layer PLN1. For example, the second planarization layer PLN2 may be disposed while covering the first relay electrode RE1, the third relay electrode RE3 and the connection line CL located on the first planarization layer PLN1.

Referring to FIG. 10, the light emitting device formation part may be located on the second planarization layer PNL2. The light emitting device forming part may include a first light emitting device ED1 and a third light emitting device ED3 formed on the second planarization layer PNL2. The first light emitting device ED1 may be disposed in the first display area DA1, and the third light emitting device ED3 may be disposed in the third display area DA3.

The first light emitting device ED1 may be formed in an area where the first pixel electrode PE1, the intermediate layer EL, and the common electrode CE overlap. The third light emitting device ED3 may be formed in an area where the third pixel electrode PE3, the intermediate layer EL, and the common electrode CE overlap.

The first pixel electrode PE1 and the third pixel electrode PE3 may be disposed on the second planarization layer PLN2. The third pixel electrode PE3 may be connected to the third relay electrode RE3 through a hole in the second planarization layer PLN2. The first pixel electrode PE1 may be connected to the connection line CL extending from the third display area DA3 to the first display area DA1 through another hole in the second planarization layer PLN2.

A bank BK may be disposed on the first pixel electrode PE1 and the third pixel electrode PE3. The bank BK may include a plurality of bank holes, and a portion of each of the first pixel electrode PE1 and the third pixel electrode PE3 may be exposed through the plurality of bank holes. That is, the plurality of bank holes formed in the bank BK may overlap a portion of each of the first pixel electrode PE1 and the third pixel electrode PE3.

The intermediate layer EL may be disposed on the bank BK. The intermediate layer EL may contact a portion of the first pixel electrode PE1 and a portion of the third pixel electrode PE3 through a plurality of bank holes. At least one spacer SPCR may be additionally disposed between the intermediate layer EL and the bank BK.

The common electrode CE may be disposed on the intermediate layer EL. The common electrode CE may include a plurality of common electrode holes CH. A plurality of common electrode holes CH formed in the common electrode CE may be disposed in the first display area DA1.

Referring to FIG. 10, the encapsulation part may be located on the common electrode CE. The encapsulation part may include an encapsulation layer 200 formed on the common electrode CE.

The encapsulation layer 200 may be a layer capable of preventing or at least reducing moisture or oxygen from penetrating into the light emitting devices ED1 and ED3 disposed below the encapsulation layer 200.

The encapsulation layer 200 may include a first encapsulation layer PAS1, a second encapsulation layer PCL, and a third encapsulation layer PAS2. For example, the first encapsulation layer PAS1 and the third encapsulation layer PAS2 may be inorganic layers, and the second encapsulation layer PCL may be an organic layer. Since the second encapsulation layer PCL is composed of an organic layer, the second encapsulation layer PCL may function as a planarization layer.

Referring to FIG. 10, a touch sensor layer TSL may include touch sensor metals TSM and bridge metals BRG, and may further include insulating layer components such as a sensor buffer layer S-BUF, and a sensor interlayer insulating layer S-ILD, and a sensor protection layer S-PAC. Here, the sensor interlayer insulating layer S-ILD may include one or more insulating layers.

The sensor buffer layer S-BUF may be disposed on the encapsulation layer 200. The bridge metals BRG may be disposed on the sensor buffer layer S-BUF, and the sensor interlayer insulating layer S-ILD may be disposed on the bridge metals BRG.

The touch sensor metals TSM may be disposed on the sensor interlayer insulating layer S-ILD. Some of the touch sensor metals TSM may be connected to the corresponding bridge metal BRG through holes in the sensor interlayer insulating layer S-ILD.

The touch sensor metals TSM and bridge metals BRG may not overlap the transmission area TA in the first display area DA1. The touch sensor metals TSM and bridge metals BRG may be disposed in the third display area DA3. However, the touch sensor metals TSM and bridge metals BRG may be arranged so as not to overlap a third emission area EA3 of the third display area DA3. A plurality of touch sensor metals TSM may form one touch electrode (or one touch electrode line), and may be arranged in a mesh shape and electrically connected. A portion of the touch sensor metals TSM and another portion of the touch sensor metals TSM may be electrically connected through a bridge metal BRG to form one touch electrode (or one touch electrode line).

The sensor protection layer S-PAC may be disposed while covering the touch sensor metals TSM and bridge metals BRG.

Meanwhile, in the case that the display panel 110 is a built-in type including a touch sensor, at least a portion of the touch sensor metal TSM located on the encapsulation layer 200 in the display area DA may be extended and disposed along the outer inclined surface of the encapsulation layer 200, and may be electrically connected to a pad located further outside the outer inclined surface of the encapsulation layer 200. Here, the pad may be disposed in the non-display area NDA and may be a metal pattern to which the touch driving circuit 260 is electrically connected.

The display panel 110 according to embodiments of the present disclosure may further include a bank BK located on the first pixel electrode PE1 and having a bank hole exposing a portion of the first pixel electrode PE1, and an intermediate layer EL located on the bank BK and in contact with a portion of the first pixel electrode PE1 exposed through the bank hole.

As an example, there may be a hole in the bank BK which overlaps the transmission area TA. That is, there may be a hole in the bank BK which overlaps the common electrode hole CH.

As another example, a hole may not be formed in the transmission area TA in the bank BK. That is, the bank hole formed in the bank BK may not overlap with the plurality of common electrode holes CH. That is, at the point where the common electrode hole CH is located, the bank BK may be not depressed or open.

At the point where the common electrode hole CH is located, the second planarization layer PLN2 and the first planarization layer PLN1 located below the bank BK may be also not depressed or open.

The first display area DA1 may overlap an electronic device 600. The third display area DA3 may not overlap the electronic device 600. In some cases, a portion of the third display area DA3 may overlap with the electronic device 600.

The electronic device 600 overlapping the first display area DA1 may be the first electronic device 11 and/or the second electronic device 12.

The cross-sectional structure of the second display area DA2 may be the same as that of the third display area DA3. However, the first subpixel circuit SPC1 disposed in the third display area DA3 to drive the first light emitting device ED1 disposed in the first display area DA1 may be not disposed in the second display area DA2.

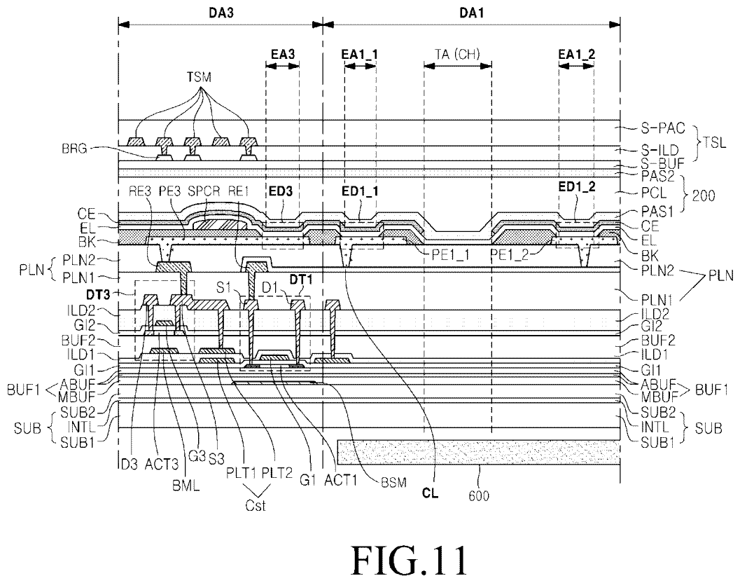

FIG. 11 is a cross-sectional view of the display panel 110 according to embodiments of the present disclosure, and is a cross-sectional view of the first display area DA1 and the third display area DA3 of the display panel 110. However, FIG. 11 is a cross-sectional view of the case where the 1:2 circuit connection method is applied, as shown in FIG. 9.

The cross-sectional view of FIG. 11 is basically the same as the cross-sectional view of FIG. 10. However, the cross-sectional view of FIG. 10 is a case of the 1:1 circuit connection method as in FIG. 8, and the cross-sectional view in FIG. 11 is a case of the 1:2 (i.e., in case of N=2) circuit connection method as in FIG. 9. Therefore, hereinafter, in explaining the cross-sectional structure of FIG. 11, it will be mainly explained features different from the cross-sectional structure of FIG. 10.

Referring to FIG. 11, two first light emitting devices ED1_1 and ED1_2 and a fourth light emitting device ED4 disposed in the first display area DA1 may be simultaneously driven by the first driving transistor DT1 disposed in the third display area DA3.

Accordingly, the connection line CL may be electrically connected to both two first pixel electrodes PE1_1 and PE1_2 of the two first light emitting devices ED1_1 and ED1_2.

The connection line CL may overlap a common electrode hole CH located between the two first light emitting devices ED1_1 and ED1_2 among the plurality of common electrode holes CH.

Referring to FIG. 11, two first emission areas EA1_1 and EA1_2 formed by the two first light emitting devices ED1_1 and ED1_2) may be emission areas which emit light of the same color.

Meanwhile, in the first display area DA1, a non-transmission area excluding the common electrode hole CH corresponding to a transmission area TA may be an area through which light does not transmit. Differently, a non-transmission area excluding the common electrode hole CH corresponding to the transmission area TA may have a significantly low transmittance.

The non-transmission area in the first display area DA1 may have a lower transmittance than the transmittance of the transmission area TA. However, the transmittance of the non-transmission area in the first display area DA1 may be higher than the transmittance of the second display area DA2.

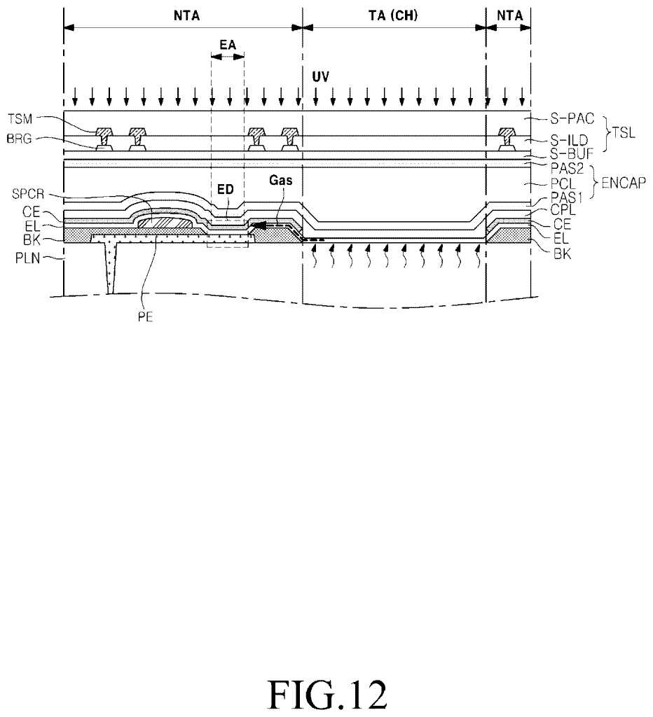

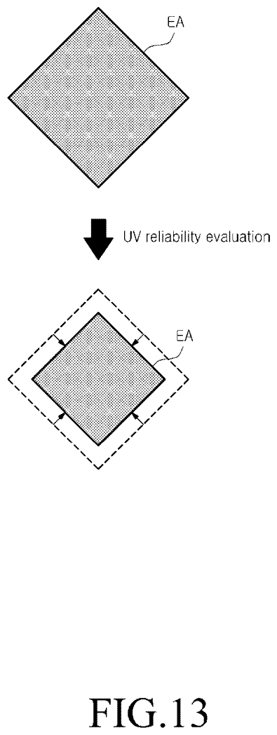

FIG. 12 illustrates a process for evaluating ultraviolet ray reliability of the display panel 110 according to embodiments of the present disclosure. FIG. 13 illustrates a pixel shrinkage phenomenon according to an ultraviolet ray reliability evaluation process of the display panel 110 according to embodiments of the present disclosure. However, the stacked structure in FIG. 12 is the same as the stacked structure in FIGS. 6, 10 and 11. Accordingly, it will be omitted the description of the same layers.

The first display area DA1 overlapping an electronic device 600 may be a first type (as shown in FIGS. 4 to 6) or a second type (as shown in FIGS. 7 to 11).

Regardless of whether the first display area DA1 is a first type or a second type, the first display area DA1 may include a transmission area TA and a non-transmission area NTA. In addition, the second display area DA2 and the third display area DA3 may also include a non-transmission area NTA.

The non-transmission area NTA included in the first to third display areas DA1, DA2 and DA3 may include an emission area EA in which the light emitting device ED is formed.

A common electrode CE may be disposed in the non-transmission area NTA.

However, in the transmission area TA, the common electrode CE may be not disposed, and the common electrode hole HC may be formed.

An ultraviolet ray reliability evaluation process may be performed during manufacturing the display panel 110.

During the ultraviolet ray reliability evaluation process, ultraviolet rays (UV) may be irradiated to an upper surface of the display panel 110. In the non-transmission area NTA, ultraviolet rays (UV) incident on the display panel 110 may be blocked by the common electrode CE and may not reach the planarization layer PLN. However, in the transmission area TA, ultraviolet rays (UV) incident on the display panel 110 may reach the planarization layer PLN through the common electrode hole CH.

If the ultraviolet rays (UV) reach the planarization layer PLN, gas may be generated in the planarization layer PLN. This phenomenon may be called “out-gassing phenomenon.”

During the ultraviolet ray reliability evaluation process, gas generated in the planarization layer PLN in the transmission area TA may be transferred to the adjacent emission area EA along the intermediate layer EL. The gas transferred to the adjacent emission area EA may exist at the edge of the light emitting device ED, and as a result, there may be decreased the area of the emission area EA, as shown in FIG. 13. This phenomenon may be called “pixel shrinkage phenomenon.”

Due to the pixel shrinkage phenomenon, the luminance of the light emitting device ED in which pixel shrinkage occurs may be decreased, thereby reducing image quality. In addition, due to pixel shrinkage, there may be reduced the lifespan of the light emitting device ED in which pixel shrinkage occurs.

Accordingly, the display device 100 according to embodiments of the present disclosure may have a structure to prevent pixel shrinkage due to gas release in the transmission area TA.

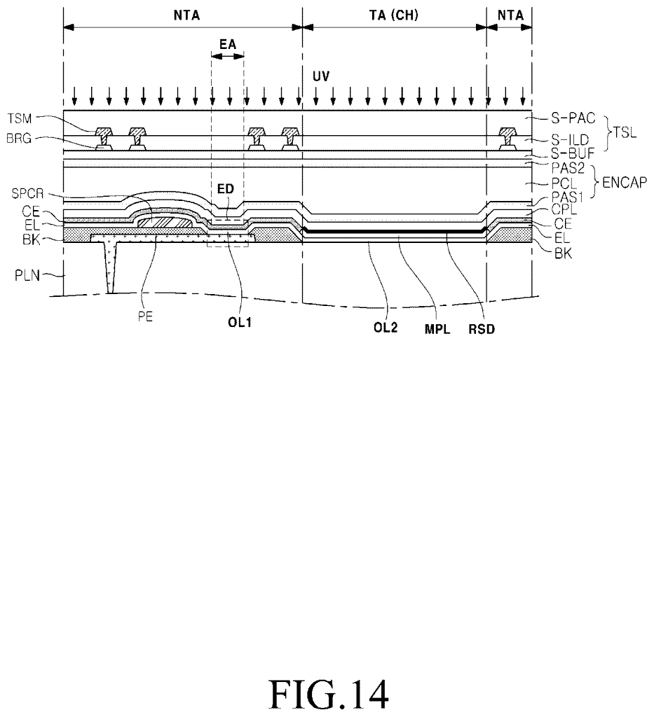

Hereinafter, it will be described an ultraviolet ray reliability improvement structure (i.e., pixel shrinkage prevention structure) of the display panel 110 according to embodiments of the present disclosure in detail with reference to FIGS. 14 to 22.

FIG. 14 is a cross-sectional view of a display panel having an ultraviolet ray reliability improvement structure according to embodiments of the present disclosure.

Referring to FIG. 14, the display panel 110 according to embodiments of the present disclosure may include a transmission area TA through which light can transmit, and a non-transmission area NTA through which light is not transmitted or has a very low transmittance.

The transmission t area TA may be included in the first display area DA1.

The non-transmission area NTA may be included in the first display area DA1 and the second display area DA2, and may also be included in the third display area DA3. The non-transmission area NTA may include an emission area EA in which the light emitting device ED is formed.

A substrate SUB may be divided into a transmission area TA and a non-transmission area NTA.

Insulating layers may be disposed on the substrate SUB. For example, the insulating layers disposed on the substrate SUB may include a planarization layer PLN located below the light emitting device ED.

Referring to FIG. 14, an emission area EA may be an area where the light emitting device ED is formed, and may include a pixel electrode PE on a planarization layer PLN, a first organic layer OL1 located on the pixel electrode PE and including an emission layer EML, and a common electrode CE on the first organic layer OL1.

The light emitting device ED may be formed by overlapping the pixel electrode PE, the first organic layer OL1, and the common electrode CE.

The first organic layer OL1 may be an organic layer disposed in the emission area EA and may be an intermediate layer EL disposed between the pixel electrode PE and the common electrode CE. For example, the first organic layer OL1 may include a common intermediate layer EL_COM and an emission layer EML. The common intermediate layer EL_COM may include a first common intermediate layer COM1 and a second common intermediate layer COM2. For example, the first common intermediate layer COM1 may include a hole injection layer HIL and a hole transport layer HTL. The second common intermediate layer COM2 may include an electron transport layer ETL and an electron injection layer EIL.

Referring to FIG. 14, a transmission area TA may be an area through which light can transmit, and may be an area in which the light emitting device ED is not formed.

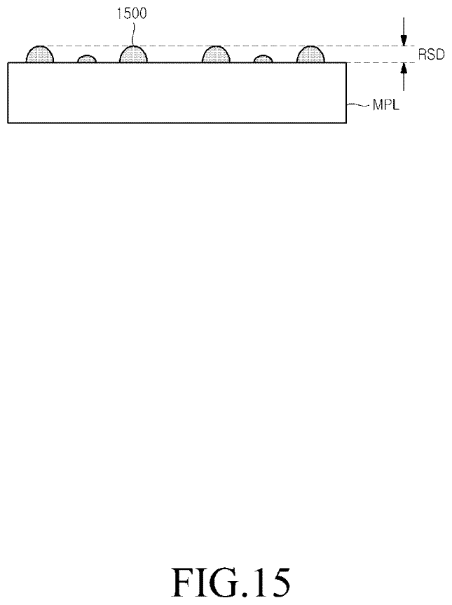

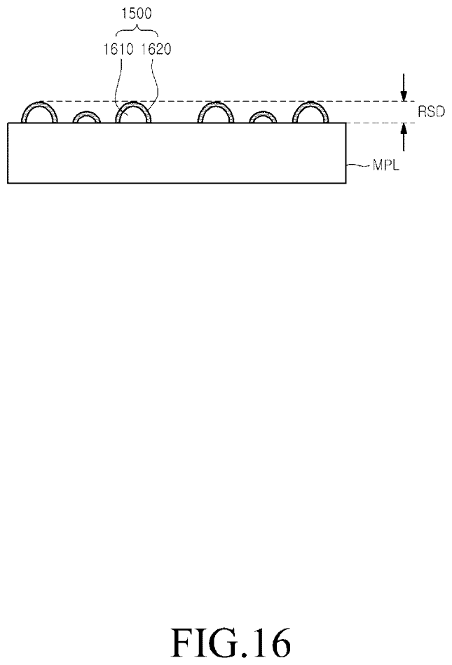

Referring to FIG. 14, the transmission area TA may include a second organic layer OL2 on the planarization layer PLN, a patterning layer MPL on the second organic layer OL2, and a residual film RSD located on the patterning layer MPL. More specifically, the residual film RSD may be formed in the opening areas of the common electrode CE formed in the transmission area TA. However, the present disclosure is not limited to it. In an embodiment, as shown in FIGS. 15 and 16 residual film RSD are not continuously formed as a film, and thus the residual film RSD may also be referred to as a residual layer.

The second organic layer OL2 may be an organic layer disposed in the transmission area TA, and may be an organic layer disposed between the insulating layer which is the planarization layer PLN and the patterning layer MPL.

If at least one of the pixel electrode PE, the emission layer EML and the common electrode CE does not exist, the light emitting device ED may be not formed and the emission area EA may be not formed. Since the transmission area TA corresponds to the common electrode hole CH, if the light emitting device ED is not formed, the emission area EA may be not formed. In addition, the pixel electrode PE may be not disposed in the transmission area TA. The emission layer EML may not exist in the transmission area TA. In some cases, an emission layer EML may be present in the transmission area TA.

Referring to FIG. 14, the display panel 110 may further include a capping layer CPL disposed on the common electrode CE and the residual film RSD.

Referring to FIG. 14, the common electrode CE may include a plurality of common electrode holes CH which overlap the transmission area TA. The residual film RSD may be disposed inside each of the plurality of common electrode holes CH.

The residual film RSD may include a metal component.

Referring to FIG. 14, a residual film RSD containing a metal component is disposed in the common electrode hole CH formed to improve the transmittance of the transmission area TA, so that, during the ultraviolet ray reliability evaluation process, the ultraviolet rays (UV) irradiated to an upper surface of the display panel 110 may be blocked by the residual film RSD and may not reach the planarization layer PLN. Accordingly, out-gassing may not occur in the transmission area TA, and thus the pixel shrinkage may not occur.

The residual film RSD may be referred to as an ultraviolet (UV) barrier.

For example, the residual film RSD may include at least a portion of the material included in the common electrode CE. The residual film RSD may include at least a portion of the material included in the first organic layer OL1.

The patterning layer MPL may be a layer disposed on the second organic layer OL2 to form the common electrode hole CH, that is, to pattern the common electrode CE.

The patterning layer MPL may include a common electrode patterning material. For example, if the common electrode CE is a cathode, the common electrode patterning material included in the patterning layer MPL may be a cathode patterning material CPM. For example, the patterning layer MPL may include a fluorine-based compound or an organic material.

For example, the common electrode CE may include at least one of silver (Ag), magnesium (Mg), silver-magnesium (AgMg), ytterbium (Yb), and silver-ytterbium (AgYb).

The second organic layer OL2 disposed in the transmission area TA may be different from the first organic layer OL1 disposed in the emission area EA.

The second organic layer OL2 may not include some of the materials included in the first organic layer OL1, or may not include some of the layers included in the first organic layer OL1. For example, the first organic layer OL1 may include an electron injection layer EIL containing an alkali metal compound. However, the second organic layer OL2 may not include an electron injection layer EIL containing an alkali metal compound.

As an example, the alkali metal compound included in the electron injection layer EIL may include lithium fluoride (LiF). As another example, the alkali metal compound included in the electron injection layer EIL may include compounds (Yb:LiF) of ytterbium (Yb) and lithium fluoride (LiF).

For example, the residual film RSD may include at least a portion of the materials included in the common electrode CE (e.g. Ag, Mg, Yb, etc.), and at least a portion of the materials included in the electron injection layer EIL (e.g. Li).

A thickness of the residual film RSD may be less than or equal to a thickness of the common electrode CE.

The thickness of the residual film RSD may be less than or equal to the thickness of the patterning layer MPL.

The thickness of the common electrode CE may be less than or equal to the thickness of the patterning layer MPL.

FIGS. 15 to 17 illustrate a residual film RSD of the display panel 110 according to embodiments of the present disclosure.

Referring to FIG. 15, the residual film RSD may include a plurality of metal particles 1500 disposed on the upper surface of the patterning layer MPL.

As an example, the sizes of each of the plurality of metal particles 1500 may be different.

As another example, each of the plurality of metal particles 1500 may have the same size.

As an example, each of the plurality of metal particles 1500 may be formed by aggregating at least a portion of the materials included in the common electrode CE.

As another example, each of the plurality of metal particles 1500 may be formed by aggregating at least a portion of the material included in the common electrode CE and at least a portion of the material included in the first organic layer OL1.

Referring to FIG. 16, the residual film RSD may include a plurality of metal particles 1500 disposed on an upper surface of the patterning layer MPL. Each of the plurality of metal particles 1500 may include a core 1610 and a shell 1620.

The core 1610 may include at least a portion of the materials included in the first organic layer OL1. The shell 1620 may include at least a portion of the materials included in the common electrode CE.

For example, the first organic layer OL1 may include an electron injection layer EIL. Each of the plurality of metal particles 1500 may include a core 1610 and a shell 1620. The core 1610 may include at least a portion of the materials included in the electron injection layer EIL. The shell 1620 may include at least a portion of the materials included in the common electrode CE.

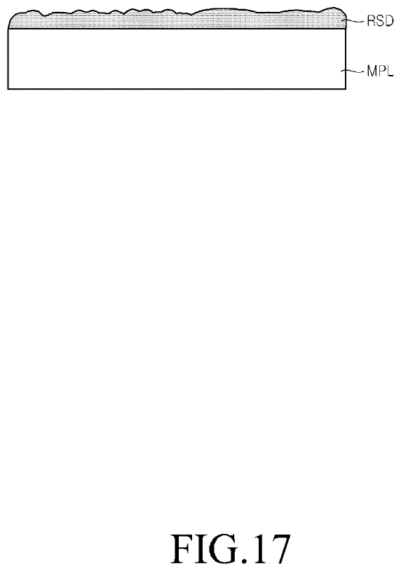

Referring to FIG. 17, the residual film RSD may be disposed on the whole upper surface of the patterning layer MPL, and may be a metal thin film without pores. That is, the residual film may completely fill the opening area of the common electrode CE. In this case, the thickness of the residual film RSD may be uniform or non-uniform. The residual film RSD may be formed in the form of a thin film by seamlessly arranging the metal particles 1500 of FIG. 15 or FIF. 16.

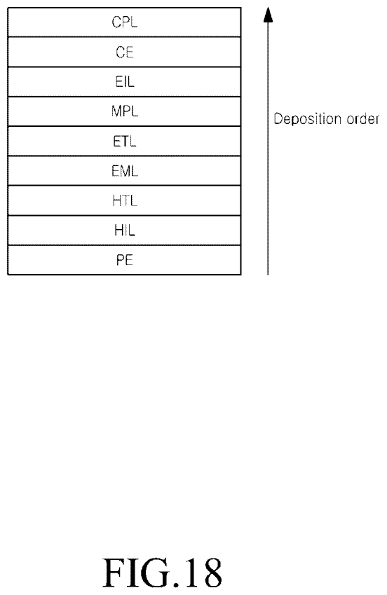

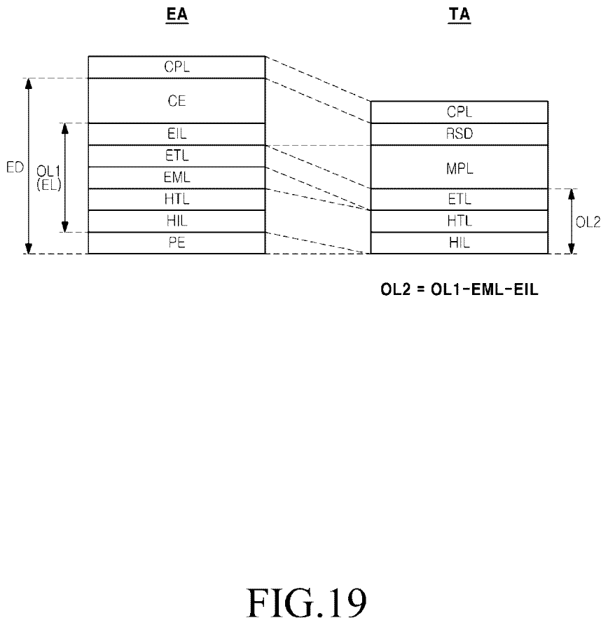

FIG. 18 illustrates a deposition sequence for forming a light emitting device forming part of a 1-stack structure in a display panel according to embodiments of the present disclosure. However, there is exemplified a case in which the pixel electrode PE is an anode and the common electrode CE is a cathode. FIG. 19 illustrates a layer stack of an emission area EA and a transmission area TA in a display panel according to embodiments of the present disclosure.

Referring to FIG. 18, in the display panel 110 according to embodiments of the present disclosure, if the light emitting device ED has a 1-stack structure, the deposition sequence for forming the light emitting device forming part may be as follows.

The pixel electrode PE may be patterned for each emission area, the hole injection layer HIL may be deposited over the entire area, and the hole transport layer HTL may also be deposited over the entire area. Here, the hole injection layer HIL and the hole transport layer HTL correspond to the first common intermediate layer COM1.

Next, the emission layer EML may be patterned for each emission area.

Then, an electron transport layer ETL may be deposited over the entire area.

Next, the patterning layer MPL may be patterned in a plurality of transmission areas TA in the first display area DA1. For example, the patterning layer MPL may include a fluorine-based compound or an organic material.

Next, an electron injection layer EIL may be deposited over the entire area. The electron injection layer EIL may include an alkali metal compound. As an example, the alkali metal compound may include lithium fluoride (LiF). As another example, the alkali metal compound may include a compound (Yb:LiF) of ytterbium (Yb) and lithium fluoride (LiF).

Next, a common electrode CE may be deposited over the entire area. For example, the common electrode CE may include at least one of silver (Ag), magnesium (Mg), silver-magnesium (AgMg), ytterbium (Yb), and silver-ytterbium (AgYb).

Next, a capping layer CPL may be deposited over the entire area.

The area in which the patterning layer MPL is disposed may include a plurality of transmission areas TA within the first display area DA1.

The area in which the patterning layer MPL is not disposed may include a non-transmission area NTA excluding the plurality of transmission areas TA in the first display area DA1, a second display area DA2, and a third display area DA3.

The area in which the patterning layer MPL is not disposed may include an emission area EA.

In area where the patterning layer MPL is not disposed, the electron injection layer EIL may be deposited on the electron transport layer ETL, and the common electrode CE may be deposited on the electron injection layer EIL. Here, the electron transport layer ETL and the electron injection layer EIL correspond to a second common intermediate layer COM2.

In the area where the patterning layer MPL is disposed, that is, in the transmission area TA, the electron injection layer EIL and the common electrode CE may not be deposited normally on the patterning layer MPL, but may be aggregated into granules to form a residual film RSD.

Hereinafter, it will be described a stacked structure in the emission area EA and transmission area TA according to the above-described deposition process.

Referring to FIG. 19, in the emission area EA, a light emitting device ED may be configured by arranging a pixel electrode PE, a hole injection layer HIL, a hole transport layer HTL, an emission layer EML, an electron transport layer ETL, and an electron injection layer EIL, and a common electrode CE in order.

In the emission area EA, the hole injection layer HIL, the hole transport layer HTL, the emission layer EML, the electron transport layer ETL, and the electron injection layer EIL may constitute a first organic layer OL1.

The first organic layer OL1 in the emission area EA may correspond to an intermediate layer EL disposed between the pixel electrode PE and the common electrode CE to form the light emitting device ED. The hole injection layer HIL and the hole transport layer HTL may form a first common intermediate layer COM1, and the electron transport layer ETL and the electron injection layer EIL may form a second common intermediate layer COM2.

In the emission area EA, the light emitting device ED may include a pixel electrode PE, a common electrode CE, and a first organic layer OL1 corresponding to an intermediate layer EL between the pixel electrode PE and the common electrode CE.

Referring to FIG. 19, in the transmission area TA, there may be sequentially disposed a pixel electrode PE, a hole injection layer HIL, a hole transport layer HTL, an electron transport layer ETL, a patterning layer MPL, and a residual film RSD.

In the transmission area TA, when the electron injection layer EIL and the common electrode CE are sequentially deposited on the patterning layer MPL, a residual film RSD may be formed. The residual film RSD may be formed on the patterning layer MPL by aggregating at least a portion of the material included in the electron injection layer EIL and at least a portion of the material included in the common electrode CE.

In the transmission area TA, a layer between the pixel electrode PE and the patterning layer MPL may correspond to a second organic layer OL2.

The second organic layer OL2 may include a hole injection layer HIL, a hole transport layer HTL, and an electron transport layer ETL. For example, the second organic layer OL2 may not include an emission layer EML between the hole transport layer HTL and the electron transport layer ETL. As another example, the second organic layer OL2 may include an emission layer EML between the hole transport layer HTL and the electron transport layer ETL.

Referring to FIG. 19, the first organic layer OL1 may include the electron injection layer EIL, but the second organic layer OL2 may not include the electron injection layer EIL.

Referring to FIG. 19, the residual film RSD may include at least a portion of the material included in the common electrode CE. For example, the residual film RSD may include at least one of silver (Ag), magnesium (Mg), silver-magnesium (AgMg), ytterbium (Yb), and silver-ytterbium (AgYb).

In addition, the residual film RSD may include at least a portion of the material included in the electron injection layer EIL. For example, the electron injection layer EIL may include an alkali metal compound. As an example, the alkali metal compound may include lithium fluoride (LiF). As another example, the alkali metal compound may include a compound (Yb:LiF) of ytterbium (Yb) and lithium fluoride (LiF).

In the case that the electron injection layer EIL includes an alkali metal compound, the residual film RSD may include at least a portion of the alkali metal compound. For example, the residual film RSD may include lithium (Li).

The residual film RSD may include at least a portion of the material included in the common electrode CE and at least a portion of the material included in the electron injection layer EIL.

As an example, the residual film RSD may include at least one of silver (Ag), magnesium (Mg), silver-magnesium (AgMg), ytterbium (Yb), and silver-ytterbium (AgYb), and at least one of ytterbium (Yb), lithium (Li) and fluorine (F). As another example, the residual film RSD may include at least one of silver (Ag), magnesium (Mg), and ytterbium (Yb), and at least one of lithium (Li) and fluorine (F). As another example, the residual film RSD may include silver (Ag), magnesium (Mg), ytterbium (Yb), and lithium (Li).

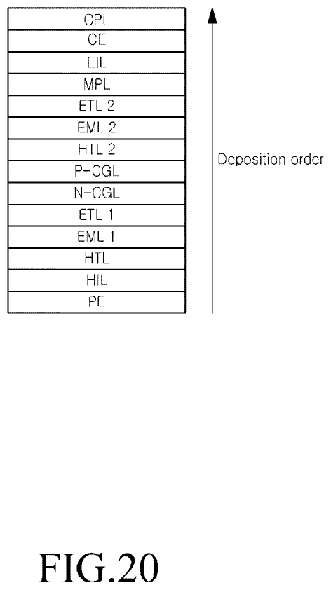

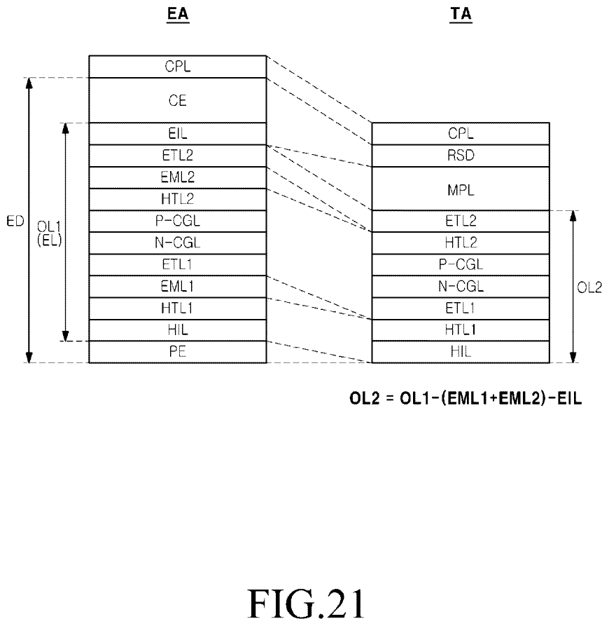

FIG. 20 illustrates a deposition sequence for forming a light emitting device forming part of a 2-stack structure in a display panel according to embodiments of the present disclosure. However, it will exemplify a case in which the pixel electrode PE is an anode and the common electrode CE is a cathode. FIG. 21 illustrates a layer stack of an emission area EA and a transmission area TA in a display panel according to embodiments of the present disclosure.

Referring to FIG. 20, in the display panel 110 according to embodiments of the present disclosure, it will described the deposition sequence for forming the light emitting device forming part in the case of the light emitting device ED of a 2-stack structure.

A pixel electrode PE may be patterned for each emission area, a hole injection layer HIL may be deposited over the entire area, and a first hole transport layer HTL1 may also be deposited over the entire area.

Next, a first emission layer EML1 may be patterned for each emission area.

Next, a first electron transport layer ETL1 may be deposited over the entire area.

Next, an N-type charge generation layer N-CGL may be deposited over the entire area, and a P-type charge generation layer P-CGL may be deposited over the entire area.

Next, a second hole transport layer HTL2 may be deposited over the entire area.

Then, a second emission layer EML2 may be patterned for each emission area.

Next, a second electron transport layer ETL2 may be deposited over the entire area.

Next, a patterning layer MPL may be patterned in a plurality of transmission areas TA in the first display area DA1. For example, the patterning layer MPL may include a fluorine-based compound or an organic material.

Next, an electron injection layer EIL may be deposited over the entire area. The electron injection layer EIL may include an alkali metal compound. As an example, the alkali metal compound may include lithium fluoride (LiF). As another example, the alkali metal compound may include a compound (Yb:LiF) of ytterbium (Yb) and lithium fluoride (LiF).

Next, a common electrode CE may be deposited over the entire area. For example, the common electrode CE may include at least one of silver (Ag), magnesium (Mg), silver-magnesium (AgMg), ytterbium (Yb), and silver-ytterbium (AgYb) . . .

Next, a capping layer CPL may be deposited over the entire area.

The area where the patterning layer MPL is disposed may include a plurality of transmission areas TA within the first display area DA1.

The area in which the patterning layer MPL is not disposed may include a non-transmission area NTA excluding a plurality of transmission areas TA in the first display area DA1, a second display area DA2 and a third display area DA3.

The area where the patterning layer MPL is not disposed may include the emission area EA.

In areas where the patterning layer MPL is not disposed, an electron injection layer EIL may be deposited on the second electron transport layer ETL2, and the common electrode CE may be deposited on the electron injection layer EIL.

In the area where the patterning layer MPL is disposed, that is, in the transmission area TA, the electron injection layer EIL and the common electrode CE may be not deposited normally on the patterning layer MPL, but may be aggregated in the form of particles so as to form a residual film RSD.

Hereinafter, it will be described a stack structure in the emission area EA and transmission area TA according to the above-described deposition process.

Referring to FIG. 21, in the emission area EA, the light emitting device ED may be configured by sequentially arranging a pixel electrode PE, a hole injection layer HIL, a first hole transport layer HTL1, a first emission layer EML1, and a first electron transport layer ETL1, a N-type charge generation layer N-CGL, a P-type charge generation layer P-CGL, a second hole transport layer HTL2, a second emission layer EML2, a second electron transport layer ETL2, an electron injection layer EIL and a common electrode CE.

In the emission area EA, a hole injection layer HIL, a first hole transport layer HTL1, a first emission layer EML1, a first electron transport layer ETL1, a N-type charge generation layer N-CGL, a P-type charge generation layer P-CGL, a second hole transport layer HTL2, a second emission layer EML2, a second electron transport layer ETL2, and an electron injection layer EIL may form a first organic layer OL1.

The first organic layer OL1 in the emission area EA may correspond to an intermediate layer EL disposed between the pixel electrode PE and the common electrode CE to form the light emitting device ED. In the emission area EA, the light emitting device ED may include a pixel electrode PE, a common electrode CE, and a first organic layer OL1 corresponding to an intermediate layer EL between the pixel electrode PE and the common electrode CE.

Referring to FIG. 21, in the transmission area TA, there may be sequentially disposed a pixel electrode PE, a hole injection layer HIL, a first hole transport layer HTL1, a first electron transport layer ETL1, an N-type charge generation layer N-CGL, a P-type charge generation layer P-CGL, a second hole transport layer HTL2, a second electron transport layer ETL2, a patterning layer MPL, and a residual film RSD.

In the transmission area TA, when the electron injection layer EIL and the common electrode CE are sequentially deposited on the patterning layer MPL, a residual film RSD may be formed. The residual film RSD may be formed on the patterning layer MPL by aggregating at least a portion of the material included in the electron injection layer EIL and at least a portion of the material included in the common electrode CE.

In the transmission area TA, a layer between the pixel electrode PE and the patterning layer MPL may be referred to as a second organic layer OL2.

The second organic layer OL2 may include a hole injection layer HIL, a first hole transport layer HTL1, a first electron transport layer ETL1, an N-type charge generation layer N-CGL, a P-type charge generation layer P-CGL, a second hole transport layer HTL2, and a second electron transport layer ETL2. For example, the second organic layer OL2 may not include a first emission layer EML1 between the first hole transport layer HTL1 and the first electron transport layer ETL1, and may not include a second emission layer EML2 between the second hole transport layer HTL2 and the second electron transport layer ETL2. As another example, the second organic layer OL2 may include a first emission layer EML1 between the first hole transport layer HTL1 and the first electron transport layer ETL1, and may include a second emission layer EML2 between the second hole transport layer HTL2 and the second electron transport layer ETL2.

Referring to FIG. 21, the first organic layer OL1 may include the electron injection layer EIL, but the second organic layer OL2 may not include the electron injection layer EIL.

Referring to FIG. 21, the residual film RSD may include at least a portion of the material included in the common electrode CE. For example, the residual film RSD may include at least one of silver (Ag), magnesium (Mg), silver-magnesium (AgMg), ytterbium (Yb), and silver-ytterbium (AgYb).

In addition, the residual film RSD may include at least a portion of the material included in the electron injection layer EIL. For example, the electron injection layer EIL may include an alkali metal compound. As an example, the alkali metal compound may include lithium fluoride (LiF). As another example, the alkali metal compound may include a compound (Yb:LiF) of ytterbium (Yb) and lithium fluoride (LiF).

If the electron injection layer EIL includes an alkali metal compound, the residual film RSD may include at least a portion of the alkali metal compound. For example, the residual film RSD may include lithium (Li).

The residual film RSD may include at least a portion of the material included in the common electrode CE and at least a portion of the material included in the electron injection layer EIL.

As an example, the residual film RSD may include at least one of silver (Ag), magnesium (Mg), silver-magnesium (AgMg), ytterbium (Yb) and silver-ytterbium (AgYb), and at least one of ytterbium (Yb), lithium (Li) and fluorine (F). As another example, the residual film RSD may include at least one of silver (Ag), magnesium (Mg), and ytterbium (Yb), and at least one of lithium (Li) and fluorine (F). As another example, the residual film RSD may include silver (Ag), magnesium (Mg), ytterbium (Yb), and lithium (Li).

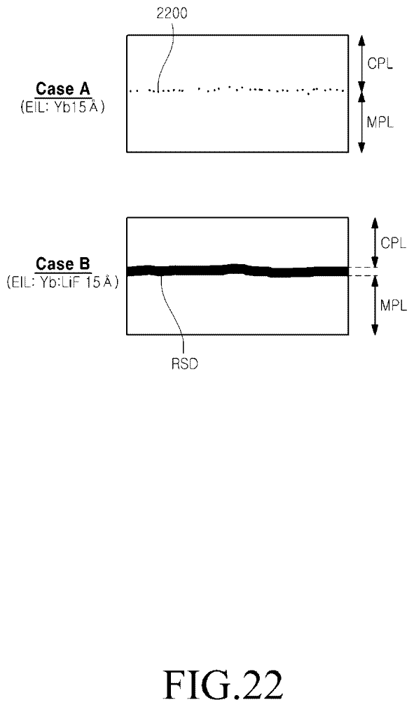

FIG. 22 illustrates whether of forming a residual film during the manufacturing process of the display panel according to embodiments of the present disclosure in a case A in which an electron injection layer EIL includes ytterbium (Yb) and a case B in which an electron injection layer EIL includes a material (e.g., Yb:LiF) including ytterbium (Yb) and lithium fluoride (LiF).

The inventors of the present application have performed a transmission electron microscopy (TEM) analysis experiment for each of a case where the electron injection layer EIL includes ytterbium (Yb) (Case A) and a case where the electron injection layer EIL includes a compound (Yb:LiF) of ytterbium (Yb) and lithium fluoride (LiF) (Case B). However, in the experiments in two cases (Case A, Case B), a thickness of the electron injection layer EIL has been set to be the same at 15 Å. In addition, the common electrode CE has been composed of silver-magnesium alloy (AgMg) or silver-ytterbium alloy (AgYb).

FIG. 22 briefly illustrates TEM images between the patterning layer MPL and the capping layer CPL for each of the two cases (Case A and Case B).

Referring to FIG. 22, when the electron injection layer EIL includes ytterbium (Yb) (Case A), in the transmission area TA, there has been formed only a small amount of fine metal pattern 2200 between the patterning layer MPL and the capping layer CPL, there has been not formed a residual film RSD sufficient to act as a UV barrier.

Referring to FIG. 22, when the electron injection layer EIL includes a compound (Yb:LiF) of ytterbium (Yb) and lithium fluoride (LiF) (Case B), in the transmission area TA, there has been formed a residual film RSD sufficient to act as an ultraviolet ray barrier between the patterning layer MPL and the capping layer CPL.

Therefore, if the electron injection layer EIL is composed of a compound (Yb:LiF) of ytterbium (Yb) and lithium fluoride (LiF), a residual film RSD with a metal component may be formed in the transmission area TA where the common electrode hole CH is formed. Accordingly, the irradiated ultraviolet rays may be blocked by the residual film RSD, thereby preventing gas release and pixel shrinkage.

TABLE 1

| Bond | ΔH_{f} |
|---|---|
| Mg—Mg | 6 |
| Yb—Yb | 21 |
| Ag—Ag | 163 |
| Li—F | 577 |
| Mg—F | 462 |
| Yb—F | 521 |
| Ag—F | 354 |

Table 1 above shows the bonding energy (ΔH_{f}) for each element.

The common electrode CE may include silver-magnesium alloy (AgMg) or silver-ytterbium alloy (AgYb), and the electron injection layer EIL) may include a compound (Yb:LiF) of ytterbium (Yb) and lithium fluoride (LiF).

When manufacturing the display panel 110 according to embodiments of the present disclosure, the electron injection layer EIL and the common electrode CE may be deposited after forming the patterning layer MPL in the transmission area TA.

Referring to Table 1, there may be recognized that a bonding energy between fluorine F included in the electron injection layer EIL and lithium (Li) included in the electron injection layer EIL, a bonding energy between fluorine (F) contained in the electron injection layer EIL and silver (Ag) contained in the common electrode CE, a bonding energy between fluorine (F) in the electron injection layer EIL and magnesium (Mg) contained in the common electrode CE, and a bonding energy between fluorine (F) contained in the electron injection layer EIL and ytterbium (Yb) contained in the common electrode CE are relatively large.

Therefore, the electron injection layer EIL is composed (Yb:LiF) of a compound of ytterbium (Yb) and lithium fluoride (LiF), so that the materials (Ag, Mg, Yb) of the common electrode CE and the materials (Li, F) of the electron injection layer EIL may combine on the patterning layer MPL to form a residual film RSD.

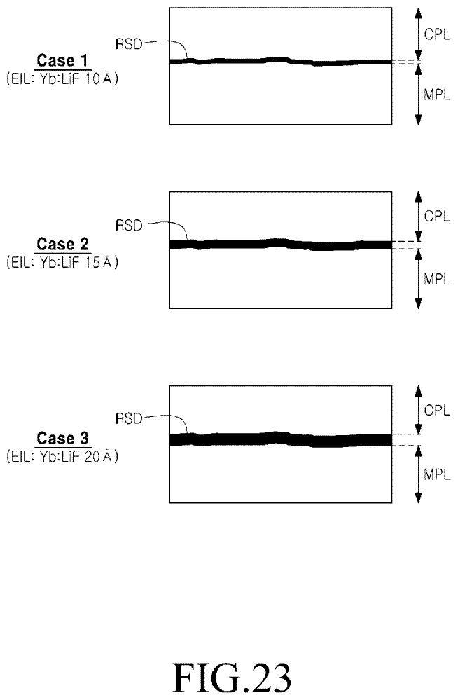

FIG. 23 illustrates a residual film RSD formed according to a thickness of an electron injection layer when a material of an electron injection layer EIL includes ytterbium (Yb) and lithium fluoride (LiF) during the manufacturing process of the display panel according to embodiments of the present disclosure.

The inventors of the present application have performed a transmission electron microscopy (TEM) analysis experiment for each of the cases having the three thicknesses of the electron injection layer EIL including a compound (Yb:LiF) of ytterbium (Yb) and lithium fluoride (LiF) (Case 1, Case 2, Case 3). In three cases (Case 1, Case 2, and Case 3), the thickness of the electron injection layer EIL has been set to 10 Å, 15 Å, and 20 Å.

FIG. 23 briefly illustrates TEM images between the patterning layer MPL and the capping layer (CPL) for three cases (Case 1, Case 2, Case 3).

Referring to FIG. 23, there may be recognized that as the thickness of the electron injection layer EIL increases, the residual film RSD becomes thicker and more clearly formed.

Therefore, as the thickness of the electron injection layer EIL made of a compound (Yb:LiF) of ytterbium (Yb) and lithium fluoride (LiF) increases, it is possible to form a thicker residual film RSD of the metal component in the transmission area TA where the common electrode hole CH is formed. Therefore, the irradiated ultraviolet rays may be blocked by the residual film RSD, thereby further preventing the gas release and pixel shrinkage.

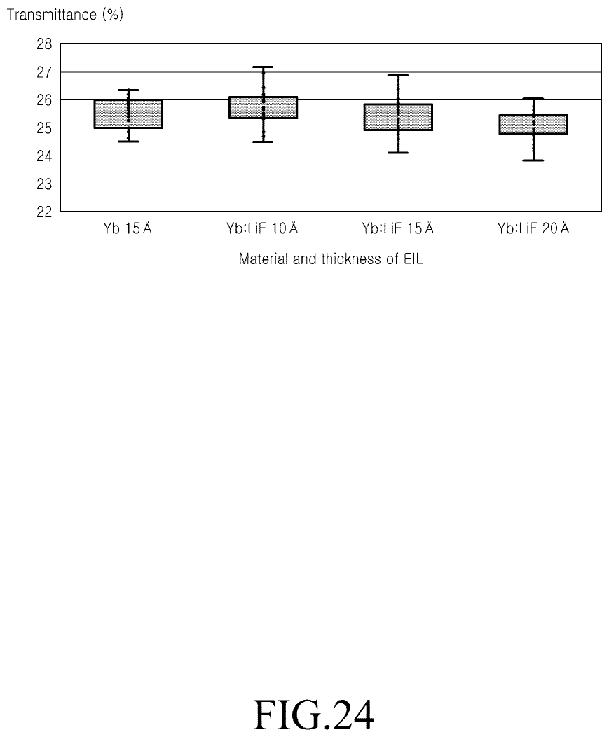

FIG. 24 illustrates a transmittance of the first display area DA1 including the transmission area TA of the display panel 110 according to embodiments of the present invention.

In order for an electronic device 600 overlapping the transmission area TA to receive light transmitted through the transmission area TA and perform a normal operation, there is required that the transmittance of the first display area DA1 is equal to or higher than the minimum transmittance.

If the electronic device 600 is an infrared sensor, the transmittance of the first display area DA1 is required to be greater than the minimum transmittance of about 20%. If the electronic device 600 is an image sensor (e.g., camera), the transmittance of the first display area DA1 is required to be greater than or equal to the minimum transmittance 20%.

According to embodiments of the present disclosure, a residual film RSD may be formed in the transmission area TA in order to prevent gas release and pixel shrinkage. Therefore, there has been checked whether the transmittance of the first display area DA1 including the transmission area TA has been deteriorated.

Referring to FIG. 24, as a result of the experiment, when the electron injection layer EIL is made of ytterbium (Yb) with a thickness of 15 A, a residual film RSD is not formed. In this case, the first display area DA1 has a transmittance of 25 to 26%. This transmittance corresponds to a reference transmittance.

If the electron injection layer EIL is made of a compound (Yb:LiF) of ytterbium (Yb) and lithium fluoride (LiF) with a thickness of 10 Å, 15 Å, and 20 Å, a residual film RSD is formed, but the first display area DA1 has a transmittance of approximately 24.8 to 25.8%. This transmittance may be similar to the reference transmittance which sufficiently enables normal operation of the electronic device 600.

Therefore, if the electron injection layer EIL is made of a compound (Yb:LiF) of ytterbium (Yb) and lithium fluoride (LiF) and a residual film RSD is formed in the transmission area TA, the transmittance of the display area DA1 may be not significantly different from the reference transmittance, and may be greater than or equal to the minimum transmittance of 20% required for normal operation of the electronic device 600.

According to embodiments of the present disclosure, the electron injection layer EIL may include a compound (Yb:LiF) of ytterbium (Yb) and lithium fluoride (LiF), and a residual film RSD may be formed in the transmission area TA, so that it is possible to prevent pixel shrinkage by preventing gas release without reducing transmittance.

Embodiments of the present disclosure described above are briefly described as follows.

A display device according to embodiments of the present disclosure may include a substrate including a display area capable of displaying an image, and an insulating layer on the substrate.

The display area may include a first display area with a plurality of emission areas and a transmission area, and a second display area located outside the first display area and including a plurality of emission areas.

Each of the plurality of emission areas may include a pixel electrode on the insulating layer, a first organic layer located on the pixel electrode and including an emission layer, and a common electrode on the first organic layer.

The transmission area may include a second organic layer on the insulating layer, a patterning layer on the second organic layer, and a residual film located on the patterning layer.

The common electrode may include a plurality of holes (i.e., common electrode holes) overlapping the transmission area, The residual film may be disposed inside each of the plurality of holes (i.e., common electrode holes).

The residual film may include a metal component.

The residual film may include at least a portion of a material included in the common electrode.

The residual film may include at least a portion of a material included in the first organic layer.

The electron injection layer may include an alkali metal compound. For example, the electron injection layer may include lithium fluoride (LiF).

The residual film may include at least a portion of the materials included in the common electrode and at least a portion of the materials included in the electron injection layer.

The common electrode may include at least one of silver (Ag), magnesium (Mg), silver-magnesium (AgMg), ytterbium (Yb) and silver-ytterbium (AgYb), and the electron injection layer may include lithium fluoride (LiF). In this case, the residual film may include at least one of silver (Ag), magnesium (Mg) and ytterbium (Yb), and at least one of lithium (Li) and fluorine (F).

The transmission area may include a second organic layer on the insulating layer, a patterning layer on the second organic layer, and a residual film located on the patterning layer.

The residual film may include a metal component.

The residual film may be a ultraviolet (UV) barrier.

21. A display device according to embodiments of the present disclosure may include a substrate comprising a display area comprising a plurality of emission areas and a transmission area; and a insulating layer on the substrate.

Each of the plurality of emission areas may include a first electrode on the insulating layer, and a first organic layer on the first electrode.

The transmission area may include a second organic layer on the insulating layer, a patterning layer on the second organic layer, and a residual layer on the patterning layer.

The residual layer may include metal.

The first organic layer may an electron injection layer.

Each of the plurality of emission areas may further include a second electrode layer on the first organic layer.

The residual layer is formed together with at least one of the electron injection layer and the second electrode. The residual layer (residual film) may include at least a portion of a material included in the second electrode (or common electrode) and at least a portion of a material included in the electron injection layer.

The patterning layer may include a fluorine-based compound or an organic material,

The electron injection layer may include an alkali metal compound.

The second electrode may include silver, magnesium, silver-magnesium, ytterbium or silver-ytterbium.

Residual layer may include a plurality of metal particles.

Each of the plurality of metal particles comprises a core and a shell, and

The core may include materials from the electron injection layer, and the shell comprises materials from the second electrode.

The residual film may be a metal thin film disposed on an upper surface of the patterning layer.

According to the embodiments of the present disclosure, there may provide a display device having a light transmission structure which allows an electronic device located below a display panel to normally receive light without exposing the electronic device receiving light to the front.

According to the embodiments of the present disclosure, there may provide a display device which does not deteriorate image quality even when irradiated with ultraviolet rays.

According to the embodiments of the present disclosure, there may provide a display device capable of prevent gas release and pixel shrinkage even when irradiated with ultraviolet rays.

According to the embodiments of the present disclosure, there may provide a display device having an ultraviolet barrier structure in a transmission area.

According to the embodiments of the present disclosure, there may provide a display device with reduced manufacturing costs through process optimization by utilizing the required processes to form a residual film acting as an ultraviolet ray barrier in the transmission area.

The above description and the accompanying drawings provide an example of the technical idea of the present disclosure for illustrative purposes only. Various modifications, additions and substitutions to the described embodiments will be readily apparent to those skilled in the art without departing from the spirit and scope of the present disclosure. In addition, the disclosed embodiments are intended to illustrate the scope of the technical idea of the present disclosure. Thus, the scope of the present disclosure is not limited to the embodiments shown.

What is claimed is:

1. A display device comprising:
a substrate including a display area that displays an image, the display area including a first display area with a plurality of emission areas and a transmission area, and a second display area located outside the first display area and including a plurality of emission areas; and
a insulating layer on the substrate,
wherein each of the plurality of emission areas comprises a pixel electrode on the insulating layer, a first organic layer on the pixel electrode and including an emission layer, and a common electrode on the first organic layer,
wherein the transmission area comprises a second organic layer on the insulating layer, a patterning layer on the second organic layer, and a residual film on the patterning layer.

2. The display device of claim 1, wherein the common electrode includes a plurality of holes that overlap the transmission area, and the residual film is inside each of the plurality of holes.

3. The display device of claim 1, wherein the residual film includes a metal component.

4. The display device of claim 1, wherein the residual film includes at least a portion of a material included in the common electrode.

5. The display device of claim 1, wherein the residual film includes at least a portion of a material included in the first organic layer.

6. The display device of claim 1, wherein a thickness of the residual film is less than or equal to a thickness of the common electrode.

7. The display device of claim 1, wherein the patterning layer includes a fluorine-based compound or an organic material.

8. The display device of claim 1, wherein the second organic layer is different from the first organic layer.

9. The display device of claim 1, wherein the first organic layer includes an electron injection layer, and the second organic layer lacks any electron injection layer.

10. The display device of claim 9, wherein the electron injection layer includes an alkali metal compound.

11. The display device of claim 9, wherein a thickness of the electron injection layer is less than or equal to a thickness of the common electrode.

12. The display device of claim 10, wherein the electron injection layer includes lithium fluoride (LiF).

13. The display device of claim 9, wherein the common electrode includes at least one of silver (Ag), magnesium (Mg), silver-magnesium (AgMg), ytterbium (Yb), or silver-ytterbium (AgYb),
wherein the electron injection layer includes lithium fluoride (LiF), and
wherein the residual film includes at least a portion of a material included the common electrode and at least a portion of a material included in the electron injection layer.

14. The display device of claim 13, wherein the residual film includes at least one of silver (Ag), magnesium (Mg), or ytterbium (Yb), and at least one of lithium (Li) and fluorine (F).

15. The display device of claim 1, wherein the residual film includes a plurality of metal particles on an upper surface of the patterning layer.

16. The display device of claim 15, wherein the first organic layer includes an electron injection layer,
wherein each of the plurality of metal particles includes a core and a shell,
wherein the core includes at least a portion of a material included in the electron injection layer, and the shell includes at least a portion of a material included in the common electrode.

17. The display device of claim 1, wherein the residual film is a metal thin film on an upper surface of the patterning layer.

18. A display device comprising:
a substrate including an emission area having a light emitting device and a transmission area that passes through light; and
an insulating layer on the substrate,
wherein the emission area comprises a pixel electrode on the insulating layer, a first organic layer located on the pixel electrode and including an emission layer, and a common electrode on the first organic layer, and
wherein the transmission area comprises a second organic layer on the insulating layer, a patterning layer on the second organic layer, and a residual film on the patterning layer.

19. The display device of claim 18, wherein the residual film includes a metal component.

20. The display device of claim 18, wherein the residual film is a ultraviolet barrier.

21. A display device comprising:
a substrate comprising a display area comprising a plurality of emission areas and a transmission area; and
a insulating layer on the substrate,
wherein each of the plurality of emission areas comprises a first electrode on the insulating layer and a first organic layer on the first electrode,
wherein the transmission area comprises a second organic layer on the insulating layer, a patterning layer on the second organic layer, and a residual layer on the patterning layer,
wherein the residual layer comprises metal.

22. The display device according to claim 21, wherein the first organic layer comprises an electron injection layer,
wherein each of the plurality of emission areas further comprises a second electrode on the first organic layer, and
wherein the residual layer comprises at least a portion of a material included in the second electrode and at least a portion of a material included in the electron injection layer.

23. The display device according to claim 22, wherein the patterning layer comprises a fluorine-based compound or an organic material,
wherein the electron injection layer includes an alkali metal compound, and
wherein the second electrode comprises silver, magnesium, silver-magnesium, ytterbium, or silver-ytterbium.

24. The display device according to claim 22, wherein the residual layer comprises a plurality of metal particles.

25. The display device according to claim 24, wherein each of the plurality of metal particles comprises a core and a shell, and
wherein the core comprises materials from the electron injection layer, and the shell comprises materials from the second electrode.

26. The display device according to claim 21, wherein the residual layer is a metal thin film on an upper surface of the patterning layer.
